(19) United States
(12) Patent Application Publication
(10) Pub. No.: US 2024/0324411 A1
(43) Pub. Date: Sep. 26, 2024

(54) DISPLAY APPARATUS

(71) Applicant: Samsung Display Co., Ltd., Yongin-Si (KR)

(72) Inventors: Donghoon Lee, Yongin-si (KR); Jangmi Kang, Yongin-si (KR); Haemin Kim, Yongin-si (KR); Myunghoon Park, Yongin-si (KR); Youngwan Seo, Yongin-si (KR); Byungchang Yu, Yongin-si (KR); Geunho Lee, Yongin-si (KR)

(21) Appl. No.: 18/604,501

(22) Filed: Mar. 14, 2024

(30) Foreign Application Priority Data
Mar. 24, 2023 (KR) 10-2023-0039096
Jun. 21, 2023 (KR) 10-2023-0079938

(51) Int. Cl. H10K 59/80; H10K 59/122

(52) U.S. Cl. CPC H10K 59/873; H10K 59/122

(57) ABSTRACT

A display apparatus is provided. The display apparatus includes a substrate including a display area and a peripheral area, a dam portion arranged in the peripheral area of the substrate and including a plurality of dams, and an encapsulation layer disposed on the substrate and the dam portion. At least one of the plurality of dams includes at least one first layer including an organic layer, and a second layer disposed on the first layer and including at least one of a conductive layer and an inorganic layer.

### CROSS-REFERENCE TO RELATED APPLICATIONS

This application is based on and claims priority, under 35 U.S.C. § 119, to Korean Patent Application No. 10-2023-0039096 filed on Mar. 24, 2023 and Korean Patent Application No. 10-2023-0079938 filed on Jun. 21, 2023 in the Korean Intellectual Property Office, the disclosures of which are incorporated by reference herein in their entireties.

### BACKGROUND

### 1. Field

One or more embodiments relate to an apparatus, and more particularly, to a display apparatus.

### 2. Description of the Related Art

Display apparatuses are configured to display data visually. Display apparatuses may provide images by using light-emitting devices. The usage of display apparatuses has diversified. Accordingly, various designs for improving the quality of display apparatuses are attempted.

### SUMMARY

One or more embodiments include a display apparatus.

Additional aspects will be set forth in part in the description which follows and, in part, will be apparent from the description, or may be learned by practice of the presented embodiments of the disclosure.

According to one or more embodiments, a display apparatus includes a substrate including a display area and a peripheral area, a dam portion arranged in the peripheral area of the substrate and including a plurality of dams, and an encapsulation layer disposed on the substrate and the dam portion, wherein at least one of the plurality of dams includes at least one first layer including an organic layer, and a second layer disposed on the first layer and including at least one of a conductive layer and an inorganic layer.

the at least one of the conductive layer and the inorganic layer may be provided in plurality so that the plurality of conductive layers, the plurality of inorganic layers, or the conductive layer and the inorganic layer are stacked.

The inorganic layer may include a plurality of inorganic layers, and the dam portion may further include a planarization layer between one of the plurality of inorganic layers and another of the plurality of inorganic layers.

A height of one of the plurality of dams may be different from a height of another of the plurality of dams.

A height of an outermost dam of the plurality of dams may be greater than a height of an innermost dam of the plurality of dams.

In the present embodiment, a number of second layers of one of the plurality of dams may be different from a number of second layers of another of the plurality of dams.

The display apparatus may further include a first electrode disposed on the substrate, an insulating layer arranged at an edge of the first electrode and having an opening overlapping a portion of the first electrode, a protective layer disposed on the insulating layer, surrounding a periphery of the first electrode, and having an opening overlapping a portion of the first electrode, a bank layer disposed on the protective layer and having an opening overlapping a portion of the first electrode, a second electrode spaced apart from the first electrode, and a sub-pixel encapsulation layer disposed on the first electrode.

The bank layer may include a first metal layer, and a second metal layer disposed on the first metal layer.

The inorganic layer may include at least one of the protective layer, the insulating layer, and the sub-pixel encapsulation layer.

The conductive layer may include at least one of the first electrode, the bank layer, and the second electrode.

The second layer may surround the first layer.

the display apparatus may further include a groove spaced apart from the dam portion.

According to one or more embodiments, a display apparatus includes a substrate including a display area and a peripheral area, a dam arranged in the peripheral area of the substrate in a single line shape surrounding at least a portion of a periphery of the display area, and an encapsulation layer disposed on the substrate and the dam, wherein the dam includes at least one first layer including an organic layer, and a second layer disposed on the first layer and including at least one of a conductive layer and an inorganic layer, wherein a height of a first portion of the dam is different from a height of a second portion of the dam.

In the present embodiment, the at least one of the conductive layer and the inorganic layer may be provided in plurality so that the plurality of conductive layers, the plurality of inorganic layers, or the conductive layer and the inorganic layer are stacked.

The inorganic layer may include a plurality of inorganic layers, and the dam may further include a planarization layer between one of the plurality of inorganic layers and another of the plurality of inorganic layers.

The dam may include a plurality of dams, and a height of a highest point of one of the plurality of dams may be different from a height of a highest point of another of the plurality of dams.

The dam may include a plurality of dams, and a height of an outermost dam of the plurality of dams may be greater than a height of an innermost dam of the plurality of dams.

The dam may include a plurality of dams, and a number of second layers of one of the plurality of dams may be different from a number of second layers of another of the plurality of dams.

A number of second layers in the first portion of the dam may be different from a number of second layers in the second portion of the dam.

The second layer may surround the first layer.

The display apparatus may further include a groove spaced apart from the dam.

The first portion of the dam and the second portion of the dam, which have different heights, may be arranged in a curved portion of the single line shape.

The display apparatus may further include a first electrode disposed on the substrate, an insulating layer arranged at an edge of the first electrode and having an opening overlapping a portion of the first electrode, a protective layer disposed on the insulating layer, surrounding a periphery of the first electrode, and having an opening overlapping a portion of the first electrode, a bank layer disposed on the protective layer and having an opening overlapping a portion of the first electrode, a second electrode spaced apart from the first electrode, and a sub-pixel encapsulation layer disposed on the first electrode.

The conductive layer may include at least one of the first electrode, the bank layer, and the second electrode.

The inorganic layer may include at least one of the protective layer, the insulating layer, and the sub-pixel encapsulation layer.

Other aspects, features, and advantages of the disclosure will become better understood through the accompanying drawings, the claims, and the detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are perspective views schematically illustrating a display apparatus according to an embodiment;

FIG. 2 is a plan view schematically illustrating a display panel included in a display apparatus, according to an embodiment;

FIG. 3A is an equivalent circuit diagram schematically illustrating a light-emitting element corresponding to a sub-pixel of a display panel and a sub-pixel circuit electrically connected to the light-emitting element, according to an embodiment;

FIG. 3B is an equivalent circuit diagram schematically illustrating a light-emitting element corresponding to a sub-pixel of a display panel and a sub-pixel circuit electrically connected to the light-emitting element, according to another embodiment;

FIG. 4A is a cross-sectional view schematically illustrating a portion of a display area of the display panel illustrated in FIG. 2;

FIG. 4B is a cross-sectional view schematically illustrating a light-emitting element of a display panel of a display apparatus, according to an embodiment;

FIG. 4C is a cross-sectional view schematically illustrating a dam portion of a display panel, according to an embodiment;

FIG. 4D is a cross-sectional view schematically illustrating a dam portion of a display panel, according to another embodiment;

FIGS. 5A to 5L are cross-sectional views schematically illustrating a method of manufacturing a display panel, according to an embodiment;

FIG. 6A is a cross-sectional view schematically illustrating a portion of a display panel, according to another embodiment;

FIG. 6B is a cross-sectional view schematically illustrating a first dam of FIG. 6A;

FIG. 7 is a perspective view schematically illustrating a display apparatus according to another embodiment;

FIG. 8 is an exploded perspective view illustrating a portion of a display apparatus, according to another embodiment;

FIG. 9 is a perspective view schematically illustrating a display panel of a display apparatus, according to another embodiment;

FIG. 10 is a cross-sectional view of the display apparatus of FIG. 7 taken along line B-B′ of FIG. 7;

FIG. 11 is a plan view schematically illustrating a state in which a display panel included in the display apparatus of FIG. 7 is unfolded, according to an embodiment;

FIG. 12 is an enlarged view of region C of FIG. 11;

FIG. 13 is a schematic cross-sectional view of a portion of the display panel of FIG. 12 taken along line D-D′ of FIG. 12, according to another embodiment;

FIG. 14 is a cross-sectional view schematically illustrating a portion of a display panel, according to another embodiment; FIG. 14 is a cross-sectional view of the display panel of FIG. 12 taken along line D-D′ of FIG. 12;

FIG. 15 is a plan view schematically illustrating a portion of a display panel, according to another embodiment;

FIGS. 16A and 16B are respectively cross-sectional views illustrating a portion of a dam of FIG. 15 taken along lines F-F′ and E-E′ of FIG. 15;

FIG. 17 is a plan view schematically illustrating a state in which a portion of a display panel is unfolded, according to another embodiment; and

FIG. 18 is a schematic cross-sectional view of the display panel of FIG. 17 taken along line H-H′ of FIG. 17.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, it may be directly or indirectly on the other layer, region, or element. That is, for example, intervening layers, regions, or elements may be present.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

The x direction, the y direction, and the z direction are not limited to three axes of the rectangular coordinate system and may be interpreted in a broader sense. For example, the x direction, the y direction, and the z direction may be perpendicular to one another or may represent different directions that are not perpendicular to one another.

When a certain embodiment may be implemented differently, a specific process order may be performed differently from the described order. For example, two consecutively described processes may be performed substantially at the same time or performed in an order that is the reverse of the order described.

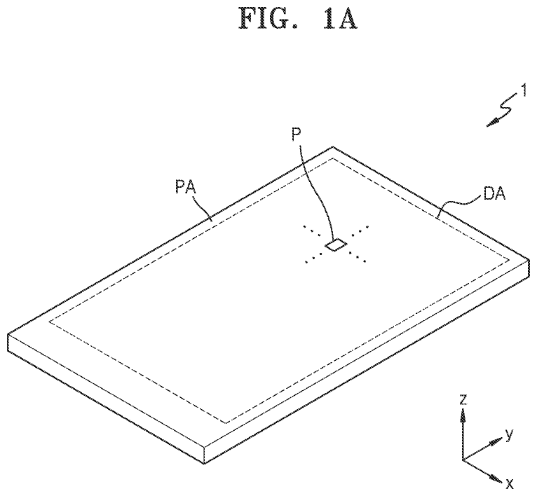

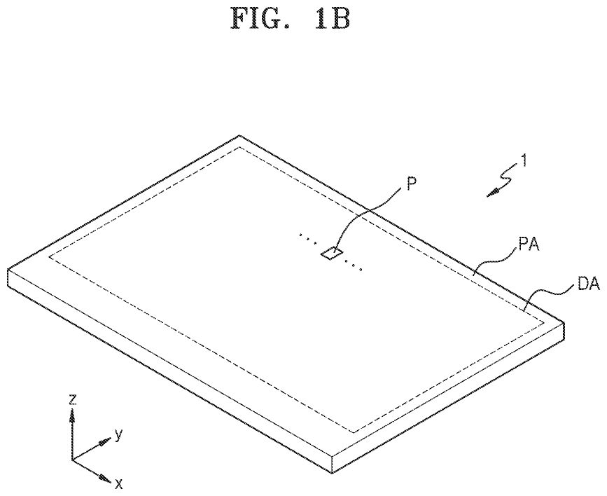

FIGS. 1A and 1B are perspective views schematically illustrating a display apparatus 1 according to an embodiment.

Referring to FIGS. 1A and 1B, the display apparatus 1 may include a display area DA and a peripheral area PA outside the display area DA. The display area DA is an area that displays an image through sub-pixels P arranged therein. The peripheral area PA is a non-display area that is outside the display area DA and does not display an image, and may completely surround the display area DA. A driver or the like configured to provide electrical signals or power to the display area DA may be arranged in the peripheral area PA. A pad, which is an area to which an electronic element or a printed circuit board may be electrically connected, may be arranged in the peripheral area PA.

In an embodiment, FIG. 1A illustrates that the display apparatus 1 has a polygonal shape (e.g., a rectangular shape) in which the length of the display area DA in the x direction is less than the length of the display area DA in the y direction, but in another embodiment, FIG. 1B illustrates that the display apparatus 1 may have a polygonal shape (e.g., a rectangular shape) in which the length of the display area DA in the y direction is less than the length of the display area DA in the x direction. Although FIGS. 1A and 1B illustrate that the display area DA has a substantially rectangular shape, the disclosure is not limited thereto. In another embodiment, the display area DA may have various shapes, such as an N-gonal shape (where N is a natural number greater than or equal to 3), a circular shape, or an elliptical shape. FIGS. 1A and 1B illustrate that the corners of the display area DA have a shape including vertices at which straight lines meet each other, but in another embodiment, the corners of the display area DA may be rounded.

Hereinafter, a case where the display apparatus 1 is an electronic device such as a smartphone is described for convenience, but the display apparatus 1 according to the disclosure is not limited thereto. The display apparatus 1 may be used in portable electronic apparatuses, such as mobile phones, smartphones, tablet personal computers, mobile communication terminals, electronic organizers, e-books, portable multimedia players (PMPs), navigation systems, and ultra mobile personal computers (UMPCs). Also, the display apparatus 1 may be used in various products, such as televisions, laptops, monitors, billboards, and Internet of things (IoT) devices. The display apparatus 1 according to an embodiment may also be applied to wearable devices, such as smart watches, watch phones, glasses-type displays, and head mounted displays (HMDs). The display apparatus 1 according to an embodiment may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles.

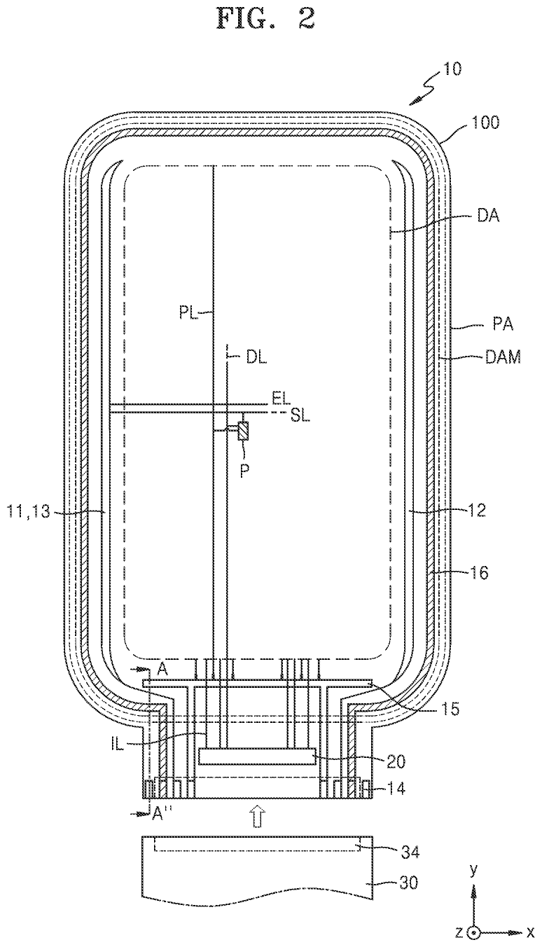

FIG. 2 is a plan view schematically illustrating a display panel 10 included in a display apparatus, according to an embodiment.

Referring to FIG. 2, the display panel 10 may include a display area DA and a peripheral area PA outside the display area DA. The display area DA is an area in which an image is displayed, and a plurality of sub-pixels P may be arranged in the display area DA. FIG. 2 illustrates that the display area DA has a substantially rectangular shape with round corners, but the disclosure is not limited thereto. As described above, the display area DA may have various shapes, such as an N-gonal shape (where N is a natural number greater than or equal to 3), a circular shape, or an elliptical shape.

The sub-pixels P may each include a display element such as an organic light-emitting diode (OLED). The sub-pixels P may each emit, for example, red light, green light, blue light, or white light.

The peripheral area PA may be outside the display area DA. External circuits configured to drive the sub-pixels P may be arranged in the peripheral area PA. For example, a first scan driving circuit 11, a second scan driving circuit 12, an emission control driving circuit 13, a terminal 14, a driving power supply line 15, and a common power supply line 16 may be arranged in the peripheral area PA. In addition, a dam portion DAM may be arranged in the peripheral area PA.

The first scan driving circuit 11 may be configured to provide a scan signal to the sub-pixel P through a scan line SL. The second scan driving circuit 12 may be arranged in parallel with the first scan driving circuit 11 with the display area DA therebetween. Some sub-pixels P in the display area DA may be electrically connected to the first scan driving circuit 11, and the remaining sub-pixels P may be electrically connected to the second scan driving circuit 12. When necessary, the second scan driving circuit 12 may be omitted, and all the sub-pixels P in the display area DA may be electrically connected to the first scan driving circuit 11.

The emission control driving circuit 13 may be arranged closer to the first scan driving circuit 11 and may be configured to provide an emission control signal to the sub-pixel P through an emission control line EL. Although FIG. 2 illustrate that the emission control driving circuit 13 is arranged only on one side of the display area DA, the emission control driving circuit 13 may be arranged on both sides of the display area DA, as the first scan driving circuit 11 and the second scan driving circuit 12.

A driving chip 20 may be arranged in the peripheral area PA. The driving chip 20 may include an integrated circuit configured to drive the display panel 10. The integrated circuit may be a data driving integrated circuit configured to generate a data signal, but the disclosure is not limited thereto.

The terminal 14 may be arranged in peripheral area PA. The terminal 14 may be exposed without being covered with an insulating layer, so as to be electrically connected to a printed circuit board 30. A terminal 34 of the printed circuit board 30 may be electrically connected to the terminal 14 of the display panel 10.

The dam portion DAM may be disposed to surround the display area DA. In this case, the dam portion DAM may include a plurality of dams.

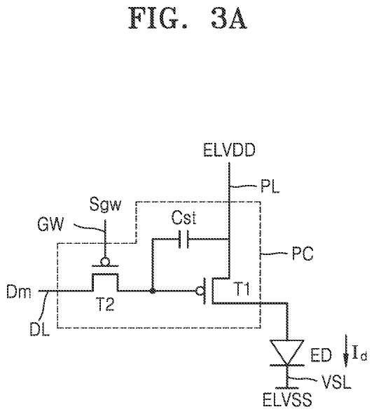

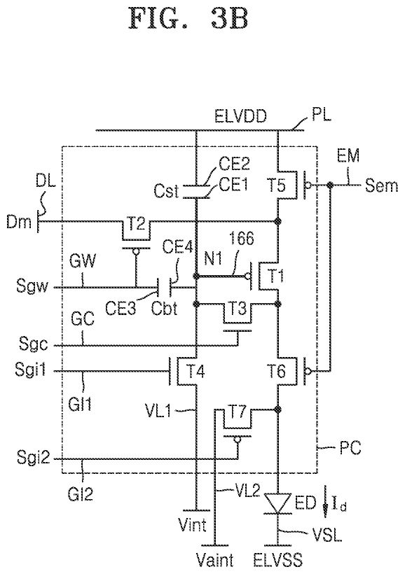

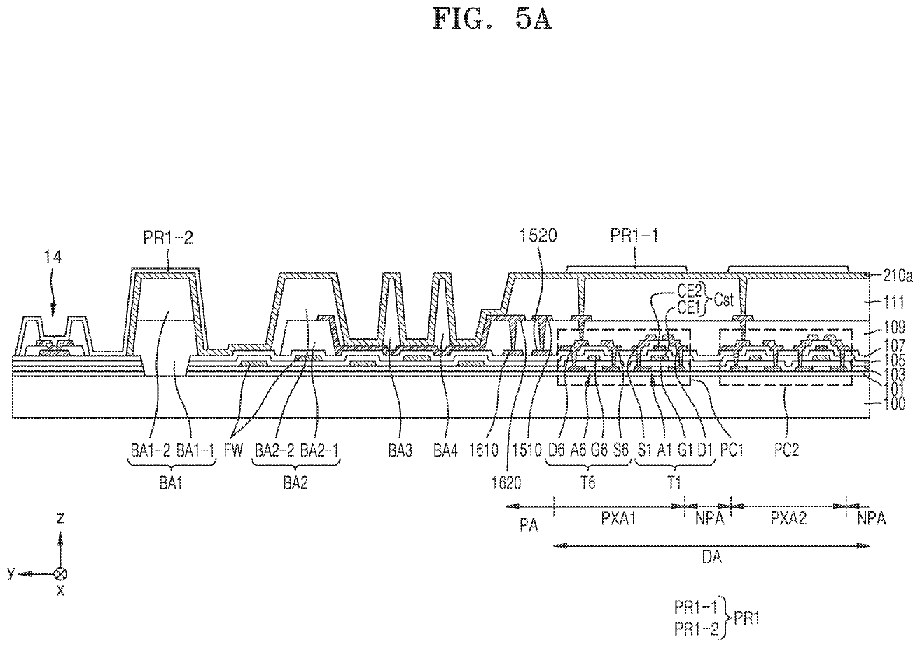

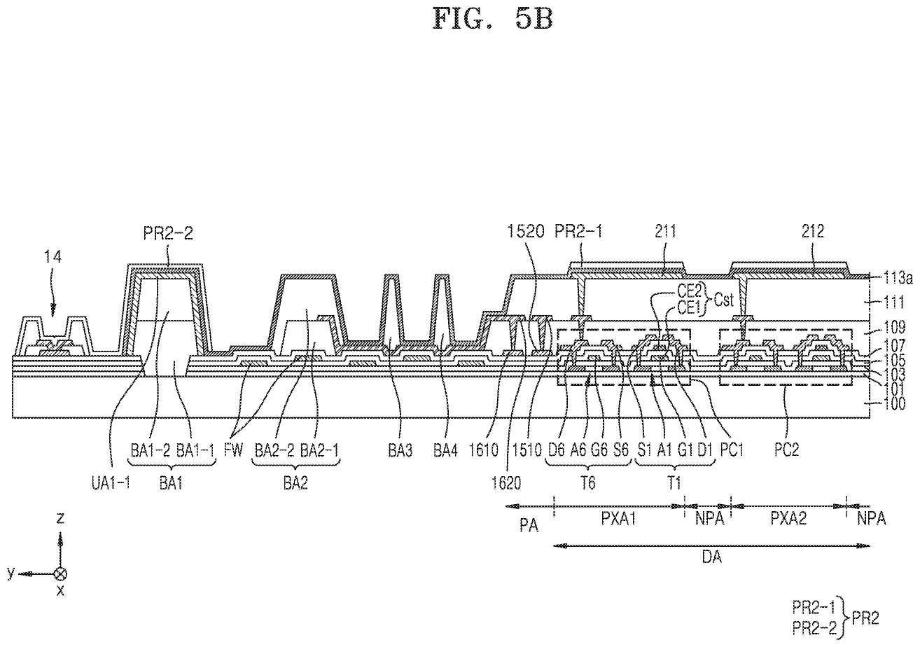

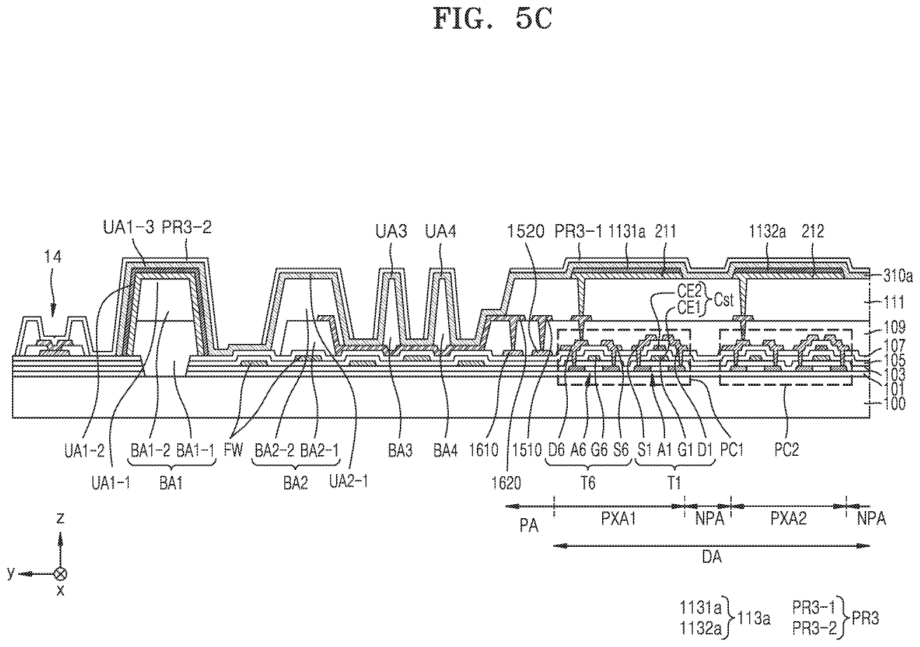

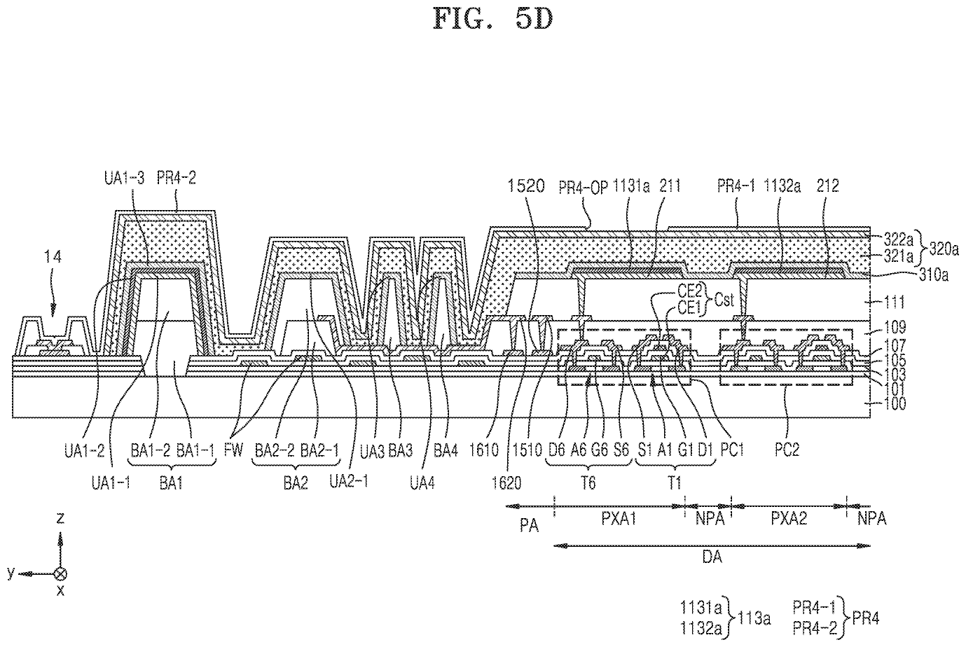

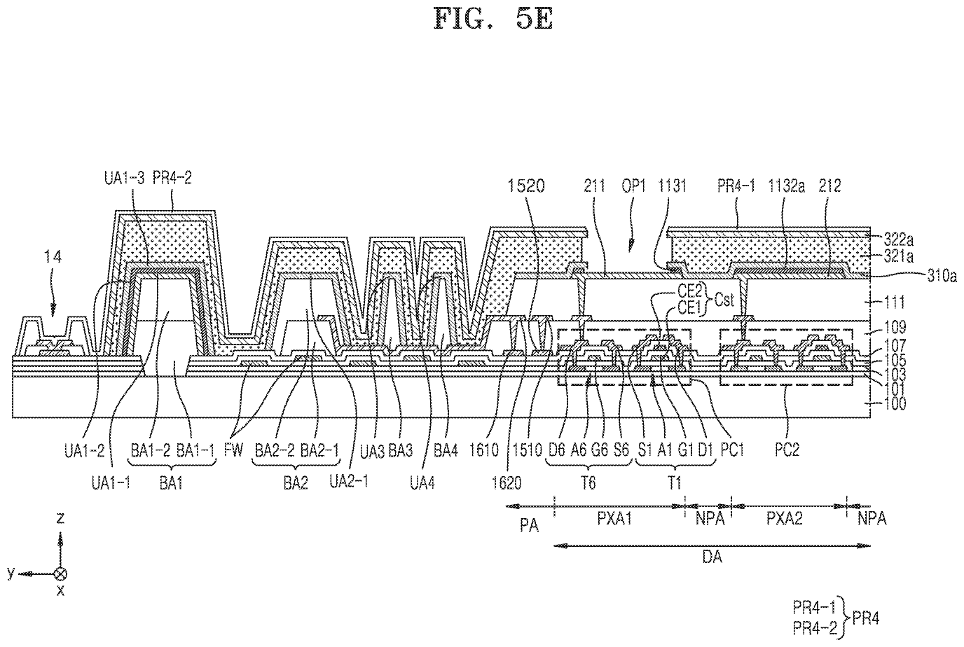

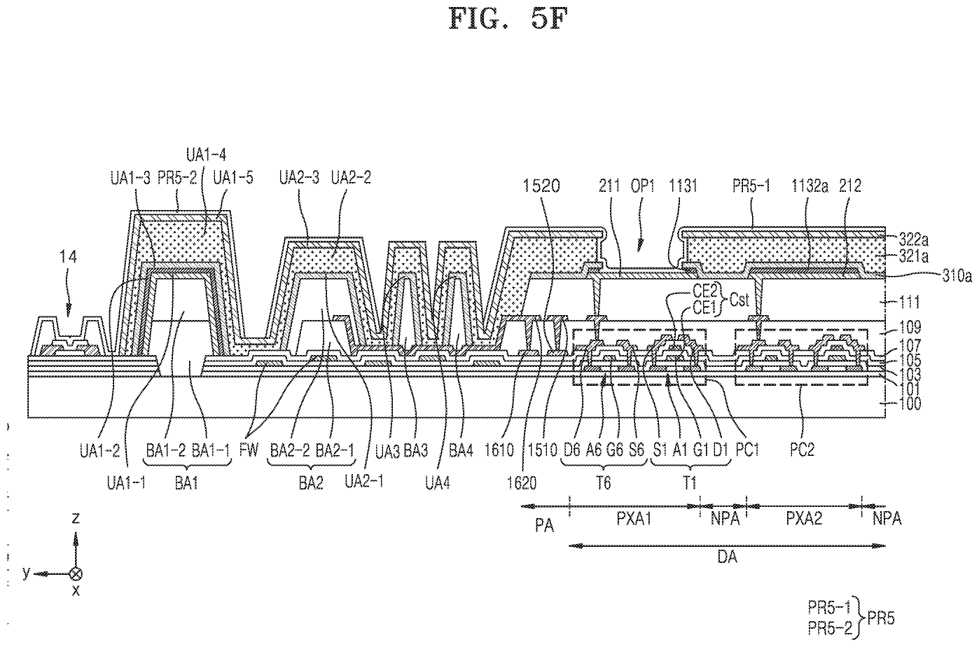

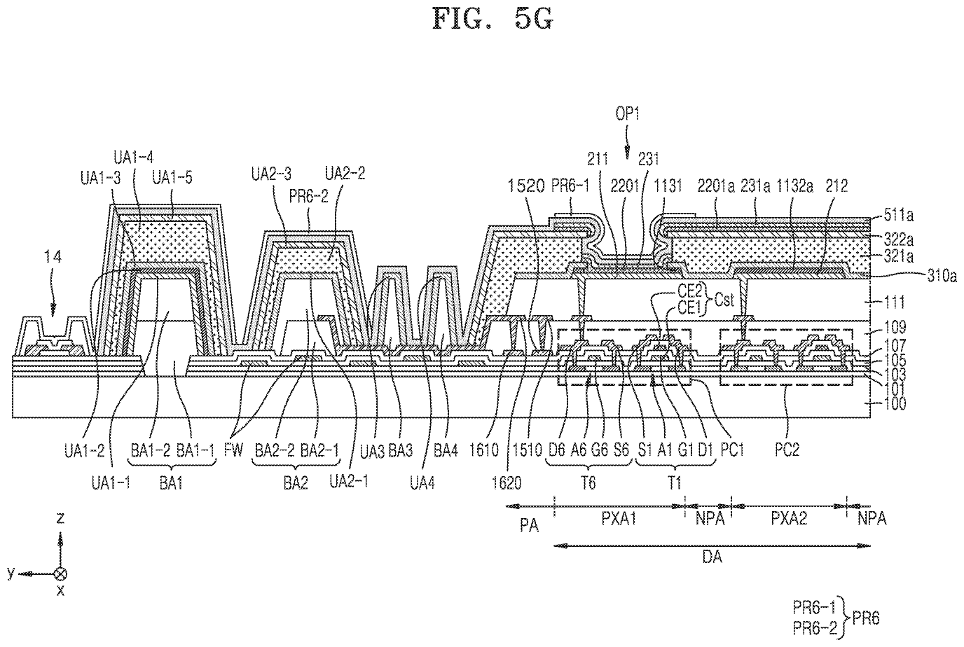

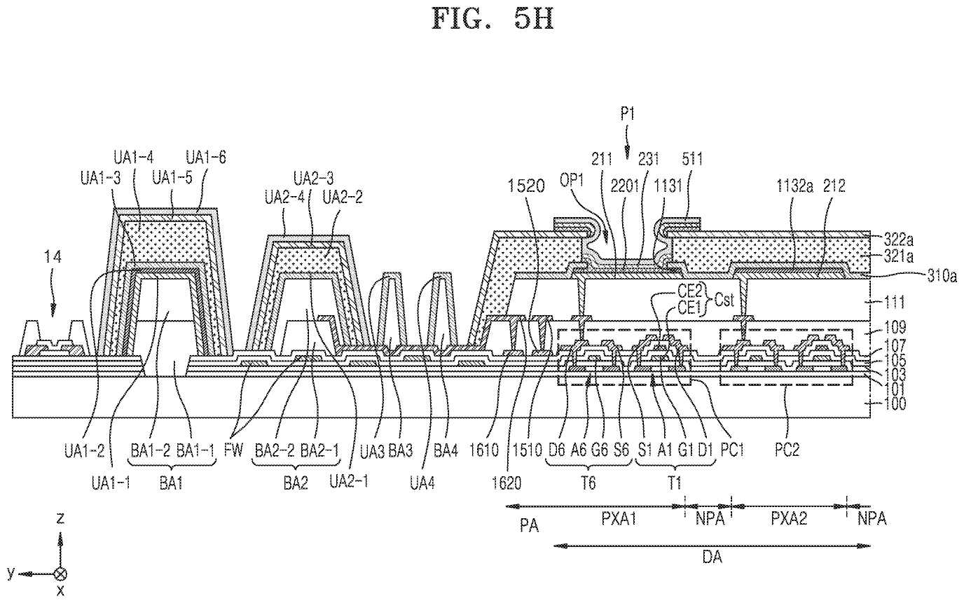

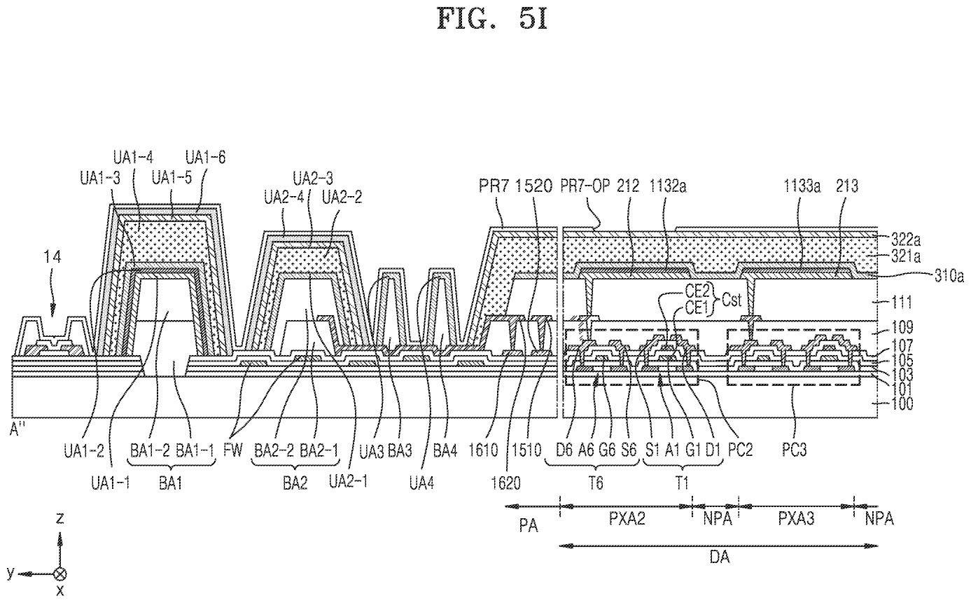

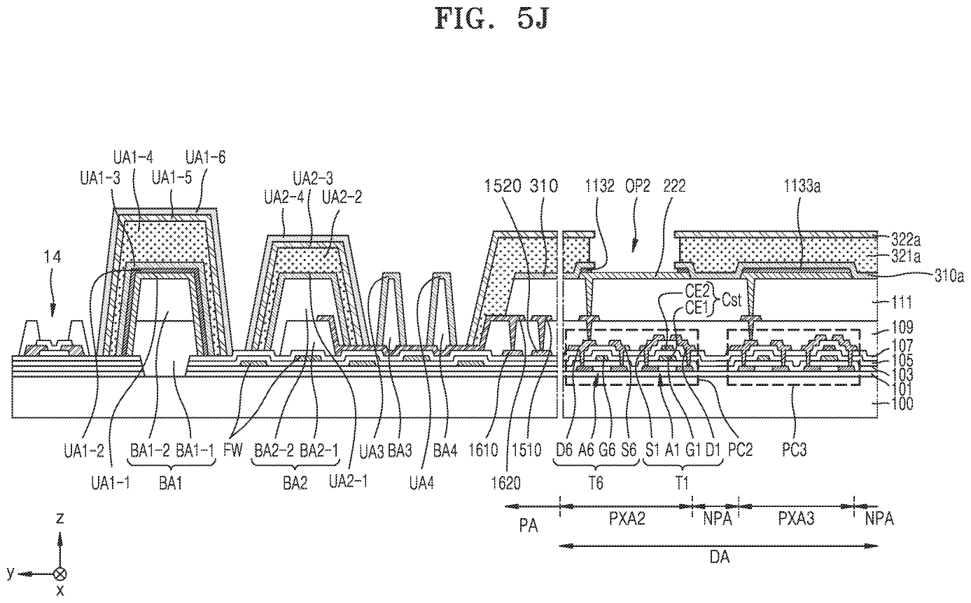

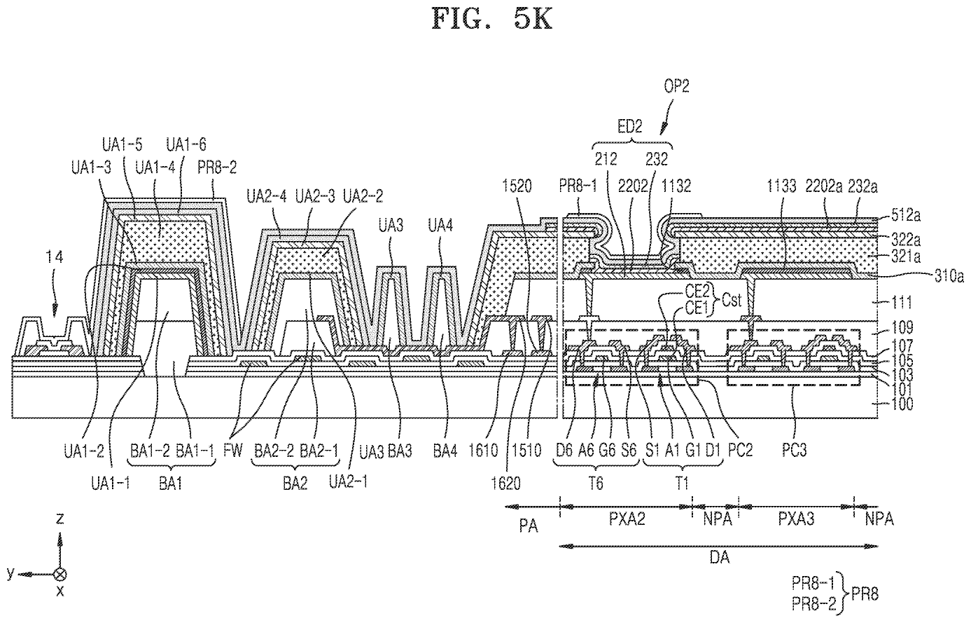

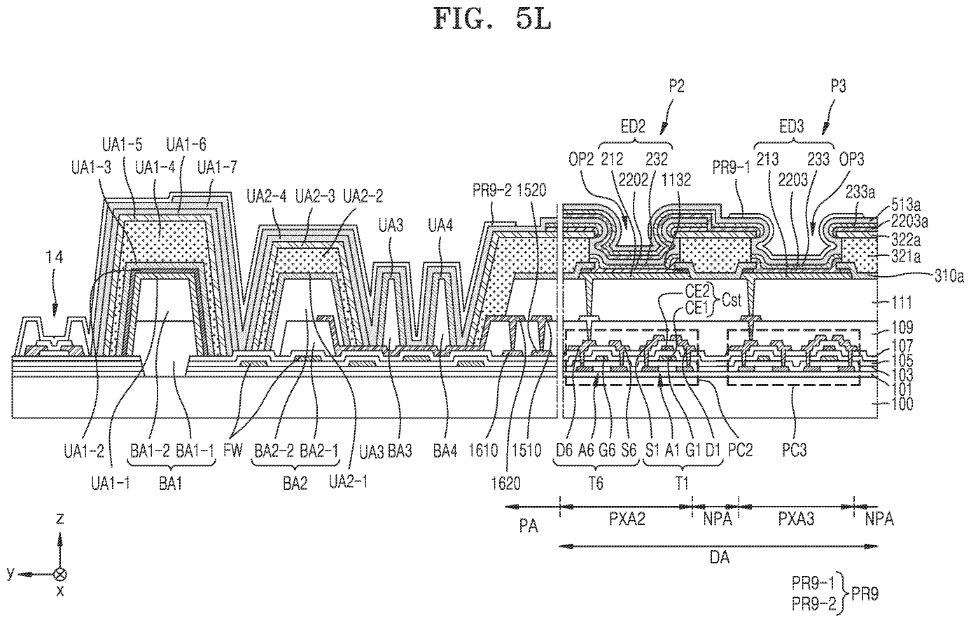

The printed circuit board 30 may be configured to transmit a signal or power from a controller (not illustrated) to the display panel 10. A control signal, which is generated by the controller, may be transmitted to driving circuits through the printed circuit board 30. In addition, the controller may be configured to transmit a driving voltage ELVDD (see FIGS. 3A and 3B) to the driving power supply line 15 and transmit a common voltage ELVSS (see FIGS. 3A and 3B) to the common power supply line 16. The driving voltage ELVDD may be transmitted to the sub-pixel P through a driving voltage line PL connected to the driving power supply line 15, and the common voltage ELVSS may be transmitted to a second electrode of the sub-pixel P through a bank layer (see the bank layer 320 of FIG. 5) connected to the common power supply line 16. The driving power supply line 15 may have a shape extending from the display area DA in one direction (e.g., the x direction). The common power supply line 16 may have a loop shape with one side open and may have a shape partially surrounding the display area DA.

On the other hand, the controller may be configured to generate a data signal, and the generated data signal may be transmitted to an input line IL through the driving chip 20 and transmitted to the sub-pixel P through a data line DL connected to the input line IL. For reference, the term “line” may refer to a “wiring.” This may be equally valid to embodiments and modifications to be described below.

FIGS. 3A and 3B are equivalent circuit diagrams schematically illustrating a light-emitting element ED corresponding to a sub-pixel of a display panel and a sub-pixel circuit PC electrically connected to the light-emitting element ED, according to an embodiment.

Referring to FIGS. 3A and 3B, the light-emitting element ED may be electrically connected to the sub-pixel circuit PC, and the sub-pixel circuit PC may include a first transistor T1, a second transistor T2, and a storage capacitor Cst.

The second transistor T2 may be configured to transmit, to the first transistor T1, a data signal Dm input through a data line DL in response to a scan signal Sgw input through a scan line GW.

The storage capacitor Cst may be connected to the second transistor T2 and a driving voltage line PL and may be configured to store a voltage corresponding to a difference between a voltage received from the second transistor T2 and a driving voltage ELVDD supplied to the driving voltage line PL.

The first transistor T1 may be connected to the driving voltage line PL and the storage capacitor Cst and may be configured to control a driving current I_{d} flowing from the driving voltage line PL to the light-emitting element ED according to a voltage stored in the storage capacitor Cst. A second electrode (e.g., a cathode) of the light-emitting element ED may be configured to receive a common voltage ELVSS. The light-emitting element ED may be configured to emit light having a certain luminance according to the driving current I_{d}.

Although FIG. 3A illustrates that the sub-pixel circuit PC includes two transistors and one storage capacitor, the disclosure is not limited thereto.

Referring to FIG. 3B, an embodiment of the sub-pixel circuit PC may include seven transistors and two capacitors.

The sub-pixel circuit PC may include first to seventh transistors T1, T2, T3, T4, T5, T6, and T7, a storage capacitor Cst, and a boost capacitor Cbt. In another embodiment, the sub-pixel circuit PC may not include the boost capacitor Cbt.

Some of the first to seventh transistors T1, T2, T3, T4, T5, T6, and T7 may each be an N-channel metal-oxide semiconductor field effect transistor (MOSFET) (NMOS), and the others thereof may each be a P-channel MOSFET (PMOS). In another embodiment, the third transistor T3, the fourth transistor T4, and the seventh transistor T7 may each be implemented as NMOS, and the others thereof may each be implemented as PMOS.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The sub-pixel circuit PC may be electrically connected to voltage lines, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting element ED via the sixth transistor T6. One of the first electrode and the second electrode of the first transistor T1 may be a source electrode and the other thereof may be a drain electrode. The first transistor T1 may be configured to supply a driving current I_{d} to the light-emitting element ED according to the switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the first electrode of the first transistor T1 and electrically connected to the driving voltage line PL via the fifth transistor T5. One of the first electrode and the second electrode of the second transistor T2 may be a source electrode and the other thereof may be a drain electrode. The second transistor T2 may be configured to be turned on in response to a scan signal Sgw received through the scan line GW and perform a switching operation of transmitting, to the first electrode of the first transistor T1, a data signal Dm received through the data line DL.

The third transistor T3 may be a compensation transistor configured to compensate for a threshold voltage of the first transistor T1. A third gate electrode of the third transistor T3 may be connected to the compensation gate line GC. A first electrode of the third transistor T3 may be connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 may be connected to the second electrode of the first transistor T1 and electrically connected to the first electrode (e.g., the anode) of the light-emitting element ED via the sixth transistor T6. One of the first electrode and the second electrode of the third transistor T3 may be a source electrode and the other thereof may be a drain electrode.

The third transistor T3 may be configured to be turned on in response to a compensation signal Sgc received through the compensation gate line GC and electrically connect the first gate electrode of the first transistor T1 to the second electrode (e.g., the drain electrode) of the first transistor T1. Therefore, the first transistor T1 may be diode-connected.

The fourth transistor T4 may be a first initialization transistor configured to initialize the first gate electrode of the first transistor T1. A fourth gate electrode of the fourth transistor T4 may be connected to the first initialization gate line GI1. A first electrode of the fourth transistor T4 may be connected to the first initialization voltage line VL1. The second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and the other thereof may be a drain electrode. The fourth transistor T4 may be configured to be turned on in response to a first initialization signal Sgi1 received through the first initialization gate line GI1 and perform an initialization operation of initializing the voltage of the first gate electrode of the first transistor T1 by transmitting a first initialization voltage Vint to the first gate electrode of the first transistor T1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode and the other thereof may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the first electrode (e.g., the anode) of the light-emitting element ED. One of the first electrode and the second electrode of the sixth transistor T6 may be a source electrode and the other thereof may be a drain electrode.

The fifth transistor T5 and the sixth transistor T6 may be configured to be simultaneously turned on in response to the emission control signal Sem received through the emission control line EM and transmit the driving voltage ELVDD to the light-emitting element ED so that the driving current I_{d} flows through the light emitting element ED.

The seventh transistor T7 may be a second initialization transistor configured to initialize the first electrode (e.g., the anode) of the light-emitting element ED. A seventh gate electrode of the seventh transistor T7 may be connected to the second initialization gate line GI2. A first electrode of the seventh transistor T7 may be connected to the second initialization voltage line VL2. The second electrode of the seventh transistor T7 may be connected to the second electrode of the sixth transistor T6 and the first electrode (e.g., the anode) of the light-emitting element ED. The seventh transistor T7 may be configured to be turned on in response to a second initialization signal Sgi2 received through the second initialization gate line GI2 and initialize the first electrode of the light-emitting element ED by transmitting a second initialization voltage Vaint to the first electrode (e.g., the anode) of the light-emitting element ED.

In some embodiments, the second initialization gate line GI2 may be a next scan line. For example, the second initialization gate line GI2 connected to the seventh transistor T7 of the sub-pixel circuit PC arranged in an ith row (where i is a natural number greater than 0) may correspond to the scan line of the sub-pixel circuit PC arranged in an (i+1)^{th} row. In another embodiment, the second initialization gate line GI2 may be the emission control line EM. For example, the emission control line EM may be electrically connected to the fifth to seventh transistors T5, T6, and T7.

The storage capacitor Cst may include the lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may be configured to store a voltage corresponding to a difference between the voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. When the scan signal Sgw supplied to the scan line GW is turned off, the boost capacitor Cbt may increase a voltage of a first node N1. When the voltage of the first node N1 is increased, a black gray scale may be clearly expressed.

The first node N1 may be an area in which the first gate electrode of the first transistor T1, the first electrode of the third transistor T3, the second electrode of the fourth transistor T4, and the fourth electrode CE4 of the boost capacitor Cbt are connected to each other.

In an embodiment, FIG. 3B illustrates that the third and fourth transistors T3 and T4 are each NMOS and the first, second, and fifth to seventh transistors T1, T2, T5, T6, and T7 are each PMOS. The first transistor T1 that directly influences the brightness of the display apparatus configured to display an image may be configured to include a semiconductor layer including polycrystalline silicon having high reliability, and thus, a high-resolution display apparatus may be implemented.

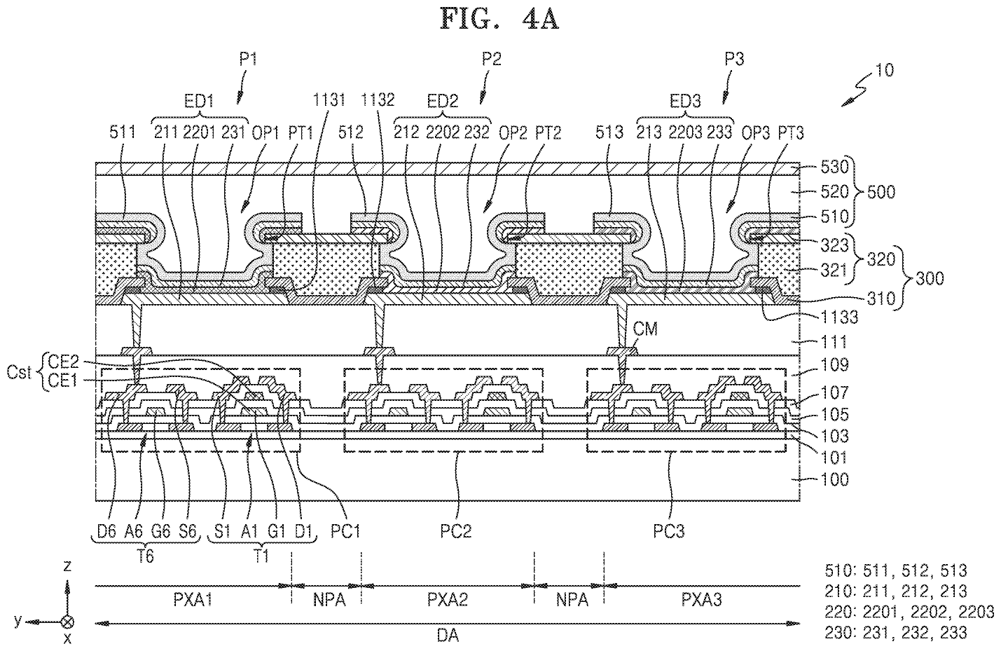

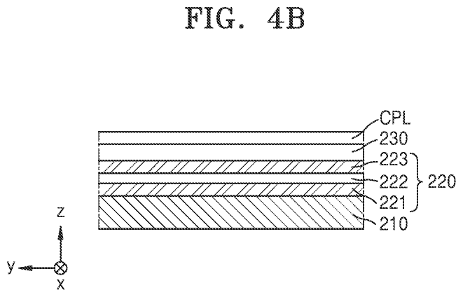

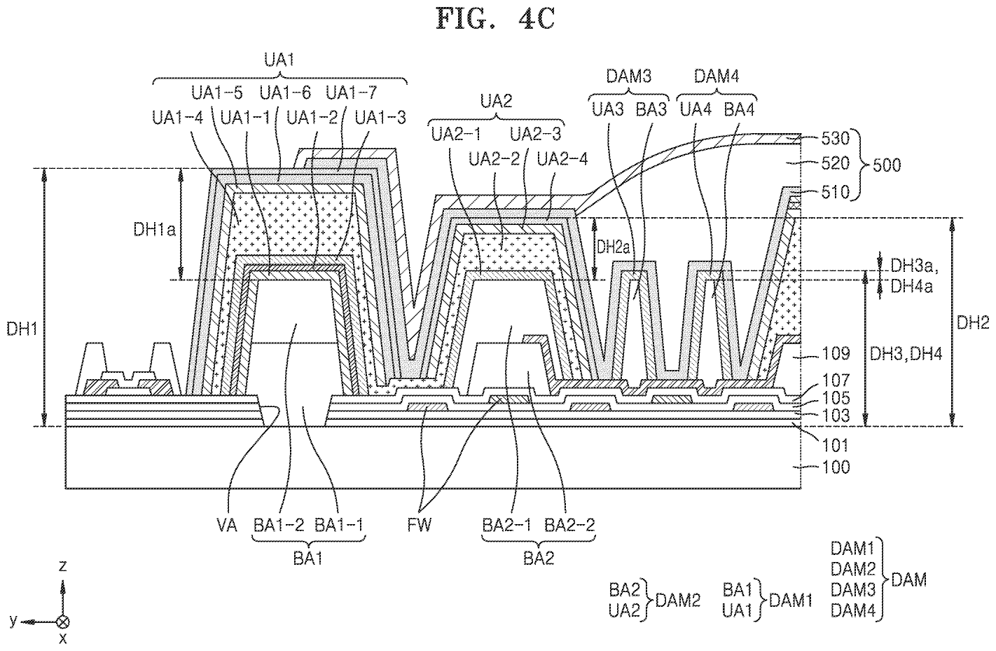

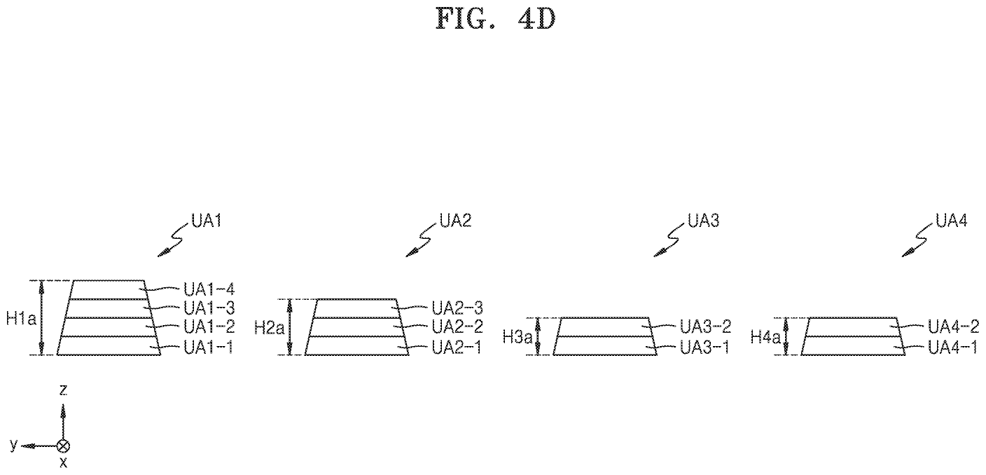

FIG. 4A is a cross-sectional view schematically illustrating a portion of the display area DA of the display panel 10 illustrated in FIG. 2. FIG. 4B is a cross-sectional view schematically illustrating the light-emitting element of the display panel of the display apparatus, according to an embodiment.

Referring to FIGS. 4A and 4B, the display area DA may include a first sub-pixel area PXA1 in which a first sub-pixel P1 is located, a second sub-pixel area PXA2 in which a second sub-pixel P2 is located, a third sub-pixel area PXA3 in which a third sub-pixel P3 is located, and a non-pixel area NPA.

A first sub-pixel circuit PC1 and a first light-emitting element ED1 electrically connected to the first sub-pixel circuit PC1 may be located in the first sub-pixel area PXA1. A second sub-pixel circuit PC2 and a second light-emitting element ED2 electrically connected to the second sub-pixel circuit PC2 may be located in the second sub-pixel area PXA2. A third sub-pixel circuit PC3 and a third light-emitting element ED3 electrically connected to the third sub-pixel circuit PC3 may be located in the third sub-pixel area PXA3.

The first to third light-emitting elements ED1 to ED3 may each include a first electrode 210, an intermediate layer 220, and a second electrode 230. For example, the first light-emitting element ED1 may include a first-first electrode 211, a first intermediate layer 2201, and a second-first electrode 231. The second light-emitting element ED2 may include a first-second electrode 212, a second intermediate layer 2202, and a second-second electrode 232. The third light-emitting element ED3 may include a first-third electrode 213, a third intermediate layer 2203, and a second-third electrode 233.

A substrate 100 may include glass or polymer resin. The substrate 100 may include a structure in which a base layer and an inorganic barrier layer each including polymer resin are stacked. Examples of the polymer resin may include polyethersulfone (PES), polyarylate (PA), polyetherimide (PEI), polyethylene naphthalate (PEN), polyethylene terephthalate (PET), polyphenylene sulfide (PPS), polyimide (PI), polycarbonate (PC), cellulose triacetate (TAC), or cellulose acetate propionate (CAP).

A buffer layer 101 may be disposed on the upper surface of the substrate 100. The buffer layer 101 may prevent impurities from penetrating into a semiconductor layer of a transistor. The buffer layer 101 may include an inorganic insulating material, such as silicon nitride, silicon oxynitride, and silicon oxide, and may include a single layer or layers including the inorganic insulating material described above.

The first sub-pixel circuit PC1, the second sub-pixel circuit PC2, and the third sub-pixel circuit PC3 may be disposed on the buffer layer 101. The first sub-pixel circuit PC1, the second sub-pixel circuit PC2, and the third sub-pixel circuit PC3 may each include a plurality of transistors and a storage capacitor, as illustrated in FIG. 3A or 3B. In an embodiment, FIG. 4A illustrates the first transistor T1, the sixth transistor T6, and the storage capacitor Cst of the sub-pixel circuit PC illustrated in FIG. 3B.

The first transistor T1 may include a first semiconductor layer A1 on the buffer layer 101, and a first gate electrode G1 overlapping a channel region of the first semiconductor layer A1. The first semiconductor layer A1 may include a silicon-based semiconductor material, for example, polysilicon. The first semiconductor layer A1 may include a channel region, and a first region and a second region respectively on both sides of the channel region. The first region and the second region are regions that include higher concentration of impurities than the channel region. One of the first region and the second region may correspond to a source region, and the other thereof may correspond to a drain region.

The sixth transistor T6 may include a sixth semiconductor layer A6 on the buffer layer 101, and a sixth gate electrode G6 overlapping a channel region of the sixth semiconductor layer A6. The sixth semiconductor layer A6 may include a silicon-based semiconductor material, for example, polysilicon. The sixth semiconductor layer A6 may include a channel region, and a first region and a second region respectively on both sides of the channel region. The first region and the second region are regions that include higher concentration of impurities than the channel region. One of the first region and the second region may correspond to a source region, and the other thereof may correspond to a drain region.

The first gate electrode G1 and the sixth gate electrode G6 may each include a conductive material including molybdenum (Mo), aluminum (Al), copper (Cu), titanium (Ti), and the like, and may include a single layer or layers including the conductive material described above. A gate insulating layer 103 for electrical insulation from the first semiconductor layer A1 and the sixth semiconductor layer A6 may be disposed below the first gate electrode G1 and the sixth gate electrode G6. The gate insulating layer 103 may include an inorganic insulating material, such as silicon nitride, silicon oxynitride, and silicon oxide, and may include a single layer or layers including the inorganic insulating material described above.

The storage capacitor Cst may include a lower electrode CE1 and an upper electrode CE2 overlapping each other. In an embodiment, the lower electrode CE1 of the storage capacitor Cst may include the first gate electrode G1. In other words, the first gate electrode G1 may include the lower electrode CE1 of the storage capacitor Cst. For example, the first gate electrode G1 and the lower electrode CE1 of the storage capacitor Cst may be integral with each other.

A first interlayer insulating layer 105 may be between the lower electrode CE1 and the upper electrode CE2 of the storage capacitor Cst. The first interlayer insulating layer 105 may include an inorganic insulating material, such as silicon oxide, silicon nitride, and silicon oxynitride, and may have a single-layer or multilayer structure including the inorganic insulating material described above.

The upper electrode CE2 of the storage capacitor Cst may include a low-resistance conductive material, such as molybdenum (Mo), aluminum (Al), copper (Cu), and/or titanium (Ti), and may include a single-layer or multilayer structure including the low-resistance conductive material described above.

A second interlayer insulating layer 107 may be disposed on the storage capacitor Cst. The second interlayer insulating layer 107 may include an inorganic insulating material, such as silicon oxide, silicon nitride, and silicon oxynitride, and may have a single-layer or multilayer structure including the inorganic insulating material described above.

A source electrode S1 and/or a drain electrode D1 electrically connected to the first semiconductor layer A1 of the first transistor T1 may be disposed on the second interlayer insulating layer 107. A source electrode S6 and/or a drain electrode D6 electrically connected to the sixth semiconductor layer A6 of the sixth transistor T6 may be disposed on the second interlayer insulating layer 107. The source electrodes S1 and S6 and/or the drain electrodes D1 and D6 may each include aluminum (Al), copper (Cu), and/or titanium (Ti), and may each include a single layer or layers including the material described above.

The second sub-pixel circuit PC2 and the third sub-pixel circuit PC3 may each have a structure identical to or similar to that of the first sub-pixel circuit PC1.

A first organic layer 109 may be disposed on the first sub-pixel circuit PC1, the second sub-pixel circuit PC2, and the third sub-pixel circuit PC3. The first organic layer 109 may include an organic insulating material, such as acryl, benzocyclobutene (BCB), PI, or hexamethyldisiloxane (HMDSO).

A connection electrode CM may be disposed on the first organic layer 109. The connection electrode CM may include aluminum (Al), copper (Cu), and/or titanium (Ti), and may include a single layer or layers including the material described above.

A second organic layer 111 may be between the connection electrode CM and the first-first electrode 211, the first-second electrode 212, and the first-third electrode 213. The second organic layer 111 may include an organic insulating material, such as acryl, BCB, PI, or HMDSO. In an embodiment, FIG. 4A illustrates that the first sub-pixel circuit PC1 and the first-first electrode 211, the second sub-pixel circuit PC2 and the first-second electrode 212, and the third sub-pixel circuit PC3 and the first-third electrode 213 are electrically connected through the connection electrode CM, but in another embodiment, the connection electrode CM may be omitted and one organic layer may be between the first to third sub-pixel circuits PC1, PC2, and PC3 and the first-first, first-second, and first-third electrodes 211, 212, and 213. Alternatively, three or more organic layers may be between the first to third sub-pixel circuits PC1, PC2, and PC3 and the first-first, first-second, and first-third electrodes 211, 212, and 213, and the first to third sub-pixel circuits PC1, PC2, and PC3 and the first-first, first-second, and first-third electrodes 211, 212, and 213 may be electrically connected through a plurality of connection metals, respectively.

The first-first electrode 211, the first-second electrode 212, and the first-third electrode 213 may be disposed on the second organic layer 111. The first-first electrode 211 may be electrically connected to the connection electrode CM through a contact hole of the second organic layer 111. The first-second electrode 212 and the first-third electrode 213 may have a structure identical to or similar to that of the first-first electrode 211.

A protective layer 310 is disposed on the second organic layer 111 so as to cover edges of the first-first electrode 211, the first-second electrode 212, and the first-third electrode 213. In other words, the protective layer 310 are formed on the entire second organic layer 111 so as to cover the first-first electrode 211, the first-second electrode 212, and the first-third electrode 213 and may have openings respectively exposing the central portions of the first-first electrode 211, the first-second electrode 212, and the first-third electrode 213.

The protective layer 310 may each include an inorganic insulating material, such as silicon oxide, silicon nitride, and silicon oxynitride, and may have a single-layer or multilayer structure including the inorganic insulating material described above.

Insulating layers 1131, 1132, and 1133 may be between each first electrode and each insulating layer so as to cover the edges of each first electrode. For example, the first-first electrode insulating layer 1131 may be between the first-first electrode 211 and the protective layer 310 so as to cover the edges of the first-first electrode 211. The first-first electrode insulating layer 1131 may be a portion of an electrode protective layer for preventing the first-first electrode 211 from being damaged due to gas or liquid materials used in an etching process or an ashing process included in a process of manufacturing a display apparatus. For example, the first-first electrode insulating layer 1131 may protect the upper surface of the first-first electrode 211 in a dry etching process for forming a first sub-pixel opening OP1 to be described below. When the first-first electrode insulating layer 1131 is removed by using wet etching after the first sub-pixel opening OP1 is formed, the first-first electrode insulating layer 1131 may remain to cover the edge of the first-first electrode 211. Similarly, the first-second electrode insulating layer 1132 may be between the first-second electrode 212 and the protective layer 310 so as to cover the edge of the first-second electrode 212, and the first-third electrode insulating layer 1133 may be between the first-third electrode 213 and the protective layer 310 so as to cover the edge of the first-third electrode 213. In this case, the insulating layers 1131, 1132, and 1133 may include a first-first electrode insulating layer 1131, a first-second electrode insulating layer 1132, and a first-third electrode insulating layer 1133 respectively arranged to correspond to both ends of the first-first electrode 211, both ends of the first-second electrode 212, and both ends of the first-third electrode 213. In some embodiments, the insulating layers 1131, 1132, and 1133 may be completely removed, so insulating layers 1131, 1132, and 1133 may be omitted.

The insulating layers 1131, 1132, and 1133 may include a material that may be selectively etched without damaging the first electrode 210. For example, the protective layer 310 may include a conductive oxide, such as indium zinc oxide (IZO) and/or indium gallium zinc oxide (IGZO).

The protective layer 310 and the insulating layers 1131, 1132, and 1133 may overlap the edges of the first electrode 210 and may prevent an electric arc or the like from occurring between the first electrode 210 and the second electrode 230 by increasing the distance between the first electrode 210 and the second electrode 230.

A bank layer 320 may be disposed on the insulating layers 1131, 1132, and 1133 and may have a first sub-pixel opening OP1 overlapping the first-first electrode 211, a second sub-pixel opening OP2 overlapping the first-second electrode 212, and a third sub-pixel opening OP3 overlapping the first-third electrode 213. The bank layer 320 may be formed on the entire insulating layers 1131, 1132, and 1133.

The bank layer 320 may include a first metal layer 321 and a second metal layer 323 including different metals from each other. The first metal layer 321 and the second metal layer 323 may include metals having different etch selectivities from each other. In an embodiment, the first metal layer 321 may include aluminum (Al), and the second metal layer 323 may include titanium (Ti). The second metal layer 323 may have a first tip PT1 extending from the upper surface of the first metal layer 321 toward the central portion of the first sub-pixel opening OP1, a second tip PT2 extending from the upper surface of the first metal layer 321 toward the central portion of the second sub-pixel opening OP2, and a third tip PT3 extending from the upper surface of the first metal layer 321 toward the central portion of the third sub-pixel opening OP3. In other words, in the first sub-pixel opening OP1, the second sub-pixel opening OP2, and the third sub-pixel opening OP3, the bank layer 320 may have an undercut structure in which a portion of the first metal layer 321 below the second metal layer 323 is removed.

A first intermediate layer 2201 may be disposed on the first-first electrode 211 through the first sub-pixel opening OP1. The first intermediate layer 2201 may include a light-emitting layer configured to emit first color light. Similarly, a second intermediate layer 2202 including a light-emitting layer configured to emit second color light may be disposed on the first-second electrodes 212 through the second sub-pixel opening OP2, and a third intermediate layer 2203 including a light-emitting layer configured to emit third color light may be disposed on the first-third electrode 213 through the third sub-pixel opening OP3.

In an embodiment, the first intermediate layer 2201 may be deposited without a separate mask, and a deposition material for forming the first intermediate layer 2201 may form a first dummy intermediate layer that is continuous from the upper surface of the second metal layer 323 to the side surface of the first tip PT1. The first intermediate layer 2201 and the first dummy intermediate layer may be separated from and spaced apart from each other by the first tip PT1.

In an embodiment, the second intermediate layer 2202 may be deposited without a separate mask, and a deposition material for forming the second intermediate layer 2202 may form a second dummy intermediate layer that is continuous from the upper surface of the second metal layer 323 to the side surface of the second tip PT2. The second intermediate layer 2202 and the second dummy intermediate layer may be separated from and spaced apart from each other by the second tip PT2.

In an embodiment, the third intermediate layer 2203 may be deposited without a separate mask, and a deposition material for forming the third intermediate layer 2203 may form a third dummy intermediate layer that is continuous from the upper surface of the second metal layer 323 to the side surface of the third tip PT3. The third intermediate layer 2203 and the third dummy intermediate layer may be separated from and spaced apart from each other by the third tip PT3.

The second-first electrode 231 may be disposed on the first intermediate layer 2201 through the first sub-pixel opening OP1. Similarly, the second-second electrode 232 may be disposed on the second intermediate layer 2202 through the second sub-pixel opening OP2, and the second-third electrode 233 may be disposed on the third intermediate layer 2203 through the third sub-pixel opening OP3.

In an embodiment, the second-first electrode 231 may be deposited without a separate mask, and a deposition material for forming the second-first electrode 231 may form a second-first dummy electrode layer that is continuous from the upper surface of the first dummy intermediate layer to the side surface of the first tip PT1. The second-first electrode 231 and the second-first dummy electrode layer may be separated from and spaced apart from each other by the first tip PT1.

In an embodiment, the second-second electrode 232 may be deposited without a separate mask, and a deposition material for forming the second-second electrode 232 may form a second-second dummy electrode layer that is continuous from the upper surface of the second dummy intermediate layer to the side surface of the second tip PT2. The second-second electrode 232 and the second-second dummy electrode layer may be separated from and spaced apart from each other by the second tip PT2.

In an embodiment, the second-third electrode 233 may be deposited without a separate mask, and a deposition material for forming the second-third electrode 233 may form a second-third dummy electrode layer that is continuous from the upper surface of the third dummy intermediate layer to the side surface of the third tip PT3. The second-third electrode 233 and the second-third dummy electrode layer may be separated from and spaced apart from each other by the third tip PT3.

In some embodiments, the first intermediate layer 2201, the second intermediate layer 2202, and the third intermediate layer 2203 may be formed by using a thermal evaporation process, and the second-first electrode 231, the second-second electrode 232, and the second-third electrode 233 may be formed by using a sputtering process. Therefore, deposition materials for forming the second-first electrode 231, the second-second electrode 232, and the second-third electrode 233 may be injected in a more oblique direction than an injecting direction of deposition materials for forming the first intermediate layer 2201, the second intermediate layer 2202, and the third intermediate layer 2203 with respect to a direction (z direction) perpendicular to the substrate 100.

The second-first electrode 231 may be in direct contact with the side surface of the first metal layer 321 on which the first intermediate layer 2201 is not formed because it is covered by the first tip PT1. Similarly, the second-second electrode 232 may be in direct contact with the side surface of the first metal layer 321 on which the second intermediate layer 2202 is not formed because it is covered by the second tip PT2, and the second-third electrode 233 may be in direct contact with the side surface of the first metal layer 321 on which the third intermediate layer 2203 is not formed because it is covered by the third tip PT3. Accordingly, the second-first electrode 231, the second-second electrode 232, and the second-third electrode 233 may be electrically connected to the bank layer 320.

As described above, the bank layer 320 may be electrically connected to the common power supply line (see the common power supply line 16 of FIG. 2) and configured to transmit the common voltage ELVSS (see FIGS. 3A and 3B) to the second-first electrode 231, the second-second electrode 232, and the second-third electrode 233.

An encapsulation layer 500 may be disposed on the first light-emitting element ED1, the second light-emitting element ED2, and the third light-emitting element ED3. In this case, the encapsulation layer 500 may include a first inorganic encapsulation layer 510, an organic encapsulation layer 520, and a second inorganic encapsulation layer 530.

The first inorganic encapsulation layer 510 may be sub-pixel inorganic encapsulation layers individually provided to seal sub-pixels (see the sub-pixels P of FIG. 2).

Specifically, a first-first inorganic encapsulation layer 511 may be formed on the second-first electrode 231 so as to seal the first light-emitting element ED1. The first-first inorganic encapsulation layer 511 may include an inorganic insulating material, such as silicon nitride, silicon oxynitride, and silicon oxide, and may include a single layer or layers including the inorganic insulating material described above.

The first-first inorganic encapsulation layer 511 may form an inorganic contact area that has relatively excellent step coverage, is in direct contact with the lower surface of the first tip PT1 and the side surface of the first metal layer 321, and completely surrounds the first light-emitting element ED1. Accordingly, the first-first inorganic encapsulation layer 511 may reduce or block a path through which impurities such as moisture and/or air penetrate into the first light-emitting element ED1.

Similarly, the first-second inorganic encapsulation layer 512 may form an inorganic contact area that is in direct contact with the lower surface of the second tip PT2 and the side surface of the first metal layer 321 and completely surrounds the second light-emitting element ED2. The first-third inorganic encapsulation layer 513 may form an inorganic contact area that is in direct contact with the lower surface of the third tip PT3 and the side surface of the first metal layer 321 and completely surrounds the third light-emitting element ED3.

The organic encapsulation layer 520 may be disposed on the first inorganic encapsulation layer 510 including the first-first inorganic encapsulation layer 511, the first-second inorganic encapsulation layer 512, and the first-third inorganic encapsulation layer 513. In this case, the first inorganic encapsulation layer 510 may be a sub-pixel encapsulation layer arranged to correspond to the sub-pixel. The organic encapsulation layer 520 may cover the first sub-pixel opening OP1, the second sub-pixel opening OP2, and the third sub-pixel opening OP3 of the bank layer 320 and provide a flat base surface to components disposed on the organic encapsulation layer 520. The organic encapsulation layer 520 may include a polymer-based material. The polymer-based material may include acrylic-based resin, epoxy-based resin, polyimide, polyethylene, and the like.

A second inorganic encapsulation layer 530 may be disposed on the organic encapsulation layer 520. The second inorganic encapsulation layer 530 may include at least one inorganic material selected from aluminum oxide, titanium oxide, tantalum oxide, hafnium oxide, zinc oxide, silicon oxide, silicon nitride, and silicon oxynitride. The second inorganic encapsulation layer 530 may prevent damage to the organic encapsulation layer 520 in subsequent processes.

Referring to FIG. 4B, the light-emitting elements respectively corresponding to the first light-emitting element ED1, the second light-emitting element ED2, and the third light-emitting element ED3 shown in FIG. 4A may each include the first electrode 210, the intermediate layer 220, and the second electrode 230. The intermediate layer 220 may include an emission layer 222.

The first electrode 210 may be formed as a (semi)transparent electrode or a reflective electrode. When the first electrode 210 is formed as a (semi)transparent electrode, the first electrode 210 may be formed of, for example, indium tin oxide (ITO), indium zinc oxide (IZO), zinc oxide (ZnO), indium oxide (In₂O₃), indium gallium oxide (IGO), or aluminum zinc oxide (AZO). When the first electrode 210 is formed as a reflective electrode, a reflective layer may be formed of Ag, Mg, Al, Pt, Pd, Au, Ni, Nd, Ir, Cr, or any compound thereof, and a layer including ITO, IZO, ZnO, or In₂O₃ may be formed on the reflective layer. In an embodiment, the first electrode 210 may have a structure in which an ITO layer, an Ag layer, and an ITO layer are sequentially stacked in this stated order.

The intermediate layer 220 may include a functional layer between the first electrode 210 and the emission layer 222 and/or between the emission layer 222 and the second electrode 230. Hereinafter, the functional layer between the first electrode 210 and the emission layer 222 is referred to as a first functional layer 221, and the functional layer between the emission layer 222 and the second electrode 230 is referred to as a second functional layer 223.

The emission layer 222 may include a high molecular weight organic material or a low molecular weight organic material that emits certain color light (red light, green light, or blue light). In another embodiment, the emission layer 222 may include an inorganic material or quantum dots.

The first functional layer 221 may include a hole transport layer (HTL) and/or a hole injection layer (HIL). The second functional layer 223 may include an electron transport layer (ETL) and/or an electron injection layer (EIL). The first functional layer 221 and the second functional layer 223 may each include an organic material.

The intermediate layer 220 may have a single stack structure including a single light-emitting layer or may have a tandem structure that is a multi-stack structure including a plurality of light-emitting layers. In the case of the tandem structure, a charge generation layer (CGL) may be between a plurality of stacks.

The second electrode 230 may include a conductive material having a low work function. For example, the second electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the second electrode 230 may further include a layer including ITO, IZO, ZnO, or In₂O₃ on the (semi)transparent layer including the material described above.

A capping layer CPL may be disposed on the second electrode 230. The capping layer CPL may be a layer provided to protect the second electrode 230 and increase light extraction efficiency. The refractive index of the capping layer CPL may be higher than the refractive index of the second electrode 230. Alternatively, the capping layer CPL may be provided by stacking layers having different refractive indices from each other. For example, the refractive index of the capping layer CPL may be about 1.7 to about 1.9. The capping layer CPL may include an organic material and may further include an inorganic insulator such as LiF.

FIG. 4C is a cross-sectional view schematically illustrating a dam portion of a display panel 10, according to an embodiment. Specially, FIG. 4C is a cross-sectional view taken along line A-A″ in FIG. 2.

Referring to FIG. 4C and in conjunction with FIGS. 2, 4A and 5D, a first bridge line 1610 connected to a common power supply line 16 may be arranged in a peripheral area PA. In this case, the first bridge line 1610 may be connected to a bank layer 320 through a first connection line 1620. In another embodiment, the first bridge line 1610 may be directly connected to the bank layer 320. Hereinafter, for convenience of explanation, a case where at least a portion of the bank layer 320 is connected to the first connection line 1620 and the first connection line 1620 is connected to the common power supply line 16 will be described in detail.

The first connection line 1620 may extend to a dam portion DAM. In this case, a fan-out line FW may be disposed below the first connection line 1620. The fan-out line FW may be a line connecting a driver and a terminal.

A second bridge line 1510 connected to a driving power supply line 15 may be arranged in the peripheral area PA. The second bridge line 1510 may be connected to a second connection line 1520.

A dam portion DAM configured to control an organic material moving from a display area DA to the peripheral area PA may be arranged in the peripheral area PA. The dam portion DAM may include a plurality of dams. For example, the dam portion DAM may include a first dam DAM1, a second dam DAM2, a third dam DAM3, and a fourth dam DAM4. At this time, the number of dams is not limited thereto and may be two or more.

The first to fourth dams DAM1 to DAM4 may have different heights from each other in a direction away from the display area DA. That is, one of a height DH1 of the first dam DAM1, a height DH2 of the second dam DAM2, a height DH3 of the third dam DAM3, and a height DH4 of the fourth dam DAM4 may be different from another of the height DH1 of the first dam DAM1, the height DH2 of the second dam DAM2, the height DH3 of the third dam DAM3, or the height DH4 of the fourth dam DAM4. In this case, the heights of the first to fourth dams DAM1 to DAM4 may be sequentially varied in a direction away from the display area DA. For example, the height DH1 of the first dam DAM1 may be greater than the height DH2 of the second dam DAM2. In addition, the height DH2 of the second dam DAM2 may be greater than the height DH3 of the third dam DAM3. The height DH3 of the third dam DAM3 may be greater than or equal to the height DH4 of the fourth dam DAM4. In this case, the height DH1 of the first dam DAM1, the height DH2 of the second dam DAM2, the height DH3 of the third dam DAM3, and the height DH4 of the fourth dam DAM4 may refer to a distance from the upper surface of the substrate 100 to the upper surface of the first dam DAM1, a distance from the upper surface of the substrate 100 to the upper surface of the second dam DAM2, a distance from the upper surface of the substrate 100 to the upper surface of the third dam DAM3, and a distance from the upper surface of the substrate 100 to the upper surface of the fourth dam DAM4, respectively.

The flow of an organic material for forming the organic encapsulation layer 520 may be controlled by forming the height DH1 of the first dam DAM1 to be greater than the heights of the other dams and sequentially decreasing the height DH1 of the first dam DAM1, the height DH2 of the second dam DAM2, and the height DH3 of the third dam DAM3.

In the above case, the first dam DAM1, the second dam DAM2, the third dam DAM3, and the fourth dam DAM4 may each include a first layer (not shown), which is a dam base layer, and a second layer (not shown), which is a dam upper layer. In this case, the first layer may include an organic layer, and the second layer may include at least one of a conductive layer and an inorganic layer.

The first dam DAM1 may include a first dam base layer BA1, which is the first layer. The first dam base layer BA1 may include a first-first dam base layer BA1-1 and a first-second dam base layer BA1-2. In this case, the first-first dam base layer BA1-1 may include the same material as that of the first organic layer 109, and the first-second dam base layer BA1-2 may include the same material as that of the second organic layer 111. The first dam DAM1 may be disposed above the substrate 100 and may include a first dam upper layer UA1, which is the second layer. The first dam upper layer UA1 may include at least one of a conductive layer and an inorganic layer. For example, the first dam upper layer UA1 may include the same material as that of at least one of the first electrode 210, the first metal layer 321, the second metal layer 323, the second-first electrode 231, the second-second electrode 232, and the second-third electrode 233, which is a conductive layer, and the same material as that of at least one of the protective layer 310, the insulating layers 1131, 1132, and 1133, and the first inorganic encapsulation layer 510. For example, the first dam upper layer UA1 may include a first-first dam upper layer UA1-1, a first-second dam upper layer UA1-2, a first-third dam upper layer UA1-3, a first-fourth dam upper layer UA1-4, a first-fifth dam upper layer UA1-5, a first-sixth dam upper layer UA1-6, and a first-seventh dam upper layer UA1-7, which are sequentially stacked on the upper surface of the first dam base layer BA1 in this stated order. In this case, one of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, and the first-seventh dam upper layer UA1-7 may include the same material as that of one of the first electrode 210, the first metal layer 321, the second metal layer 323, the second-first electrode 231, the second-second electrode 232, the second-third electrode 233, the protective layer 310, the insulating layers 1131, 1132, and 1133, and the first inorganic encapsulation layer 510. Another of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, and the first-seventh dam upper layer UA1-7 may include the same material as that of another of the first electrode 210, the first metal layer 321, the second metal layer 323, the second-first electrode 231, the second-second electrode 232, the second-third electrode 233, the protective layer 310, the insulating layers 1131, 1132, and 1133, and the first inorganic encapsulation layer 510. For convenience of explanation, a case where the first-first dam upper layer UA1-1 includes the same material as that of the first-first electrode 211, the first-second dam upper layer UA1-2 includes the same material as that of the protective layer 310, the first-third dam upper layer UA1-3 includes the same material as that of the second electrode 230, the first-fourth dam upper layer UA1-4 includes the same material as that of the first metal layer 321, the first-fifth dam upper layer UA1-5 includes the same material as that of the second metal layer 323, the first-sixth dam upper layer UA1-6 includes the same material as that of the first-first inorganic encapsulation layer 511, and the first-seventh dam upper layer UA1-7 includes the same material as that of the first-second inorganic encapsulation layer 512 will be described in detail.

One of the first-first to first-seventh dam upper layers UA1-1 to UA1-7 may be disposed to surround another of the first-second dam base layer BA1-2 and the first-first to first-seventh dam upper layers UA1-1 to UA1-7. For example, the first-first dam upper layer UA1-1 may be disposed to cover at least a portion of the outer surface of the first-second dam base layer BA1-2, and the first-second dam upper layer UA1-2 may be disposed to cover at least a portion of the outer surface of the first-first dam upper layer UA1-1. In addition, the first-third dam upper layer UA1-3 may be disposed to cover at least a portion of the outer surface of the first-second dam upper layer UA1-2, and the first-fourth dam upper layer UA1-4 may be disposed to cover at least a portion of the outer surface of the first-third dam upper layer UA1-3. The first-fifth dam upper layer UA1-5 may be disposed to cover at least a portion of the outer surface of the first-fourth dam upper layer UA1-4, and the first-sixth dam upper layer UA1-6 may be disposed to cover at least a portion of the outer surface of the first-fifth dam upper layer UA1-5. The first-seventh dam upper layer UA1-7 may be disposed to cover at least a portion of the outer surface of the first-sixth dam upper layer UA1-6.

A valley VA, from which at least one of the buffer layer 101, the gate insulating layer 103, the first interlayer insulating layer 105, and the second interlayer insulating layer 107 is removed, may be disposed below the first dam DAM1.

The second dam DAM2 may include a second dam base layer BA2, which is the first layer, and a second dam upper layer UA2, which is the second layer. The second dam base layer BA2 may include a second-first dam base layer BA2-1 and a second-second dam base layer BA2-2, which are sequentially stacked in this stated order. The second-first dam base layer BA2-1 may include the same material as that of the first organic layer 109, and the second-second dam base layer BA2-2 may include the same material as that of the second organic layer 111. The second dam upper layer UA2 may include at least one of a conductive layer and an inorganic layer. For example, the second dam upper layer UA2 may include the same material as that of at least one of the first electrode 210, the first metal layer 321, the second metal layer 323, the second-first electrode 231, the second-second electrode 232, and the second-third electrode 233, which is a conductive layer, and/or the same material as that of at least one of the protective layer 310, the insulating layers 1131, 1132, and 1133, and the first inorganic encapsulation layer 510. The second dam upper layer UA2 may include a second-first dam upper layer UA2-1, a second-second dam upper layer UA2-2, a second-third dam upper layer UA2-3, and a second-fourth dam upper layer UA2-4, which are sequentially stacked in this stated order. In this case, one of the second-first dam upper layer UA2-1, the second-second dam upper layer UA2-2, the second-third dam upper layer UA2-3, and the second-fourth dam upper layer UA2-4 may include the same material as that of one of the first electrode 210, the first metal layer 321, the second metal layer 323, the second-first electrode 231, the second-second electrode 232, the second-third electrode 233, the protective layer 310, the insulating layers 1131, 1132, and 1133, and the first inorganic encapsulation layer 510. Another of the second-first dam upper layer UA2-1, the second-second dam upper layer UA2-2, the second-third dam upper layer UA2-3, and the second-fourth dam upper layer UA2-4 may include the same material as that of another of the first electrode 210, the first metal layer 321, the second metal layer 323, the second-first electrode 231, the second-second electrode 232, the second-third electrode 233, the protective layer 310, the insulating layers 1131, 1132, and 1133, and the first inorganic encapsulation layer 510. For convenience of explanation, a case where the second-first dam upper layer UA2-1 includes the same material as that of the second electrode 230, the second-second dam upper layer UA2-2 includes the same material as that of the first metal layer 321, the second-third dam upper layer UA2-3 includes the same material as that of the second metal layer 323, and the second-fourth dam upper layer UA2-4 includes the same material as that of the first-first inorganic encapsulation layer 511 will be described in detail.

The third dam DAM3 may include a third dam base layer BA3, which is the first layer, and a third dam upper layer UA3, which is the second layer. In this case, the third dam base layer BA3 may include the first organic layer 109 and/or the second organic layer 111. The third dam upper layer UA3 may include the same material as that of at least one of the first electrode 210, the first metal layer 321, the second metal layer 323, the second-first electrode 231, the second-second electrode 232, and the second-third electrode 233, which is a conductive layer, and/or the same material as that of at least one of the protective layer 310, the insulating layers 1131, 1132, and 1133, and the first inorganic encapsulation layer 510, and may be a single layer or a plurality of stacked layers. For convenience of explanation, a case where the third dam upper layer UA3 is a single layer and includes the same material as those of the second electrode 230 will be described in detail.

The fourth dam DAM4 may include a fourth dam base layer BA4, which is the first layer, and a fourth dam upper layer UA4, which is the second layer. Because the fourth dam base layer BA4 and the fourth dam upper layer UA4 are respectively identical to or similar to the third dam base layer BA3 and the third dam upper layer UA3 described above, a detailed description thereof is omitted.

In the above case, a height DH1a of the first dam upper layer UA1, a height DH2a of the second dam upper layer UA2, a height DH3a of the third dam upper layer UA3, and a height DH4a of the fourth dam upper layer UA4 may be different from each other. For example, the height DH1a of the first dam upper layer UA1 may be greater than the height DH2a of the second dam upper layer UA2, and the height DH2a of the second dam upper layer UA2 may be greater than the height DH3a of the third dam upper layer UA3 and/or the height DH4a of the fourth dam upper layer UA4. The height DH3a of the third dam upper layer UA3 may be greater than or equal to the height DH4a of the fourth dam upper layer UA4.

The height of each dam may be controlled by making the heights of the dam upper layers of the dams different from each other.

The height of the dam upper layer may be controlled by adjusting the number of layers included in each dam upper layer. In this case, when the height of one dam upper layer is greater than the height of another dam upper layer, the number of layers included in the one dam upper layer may be greater than the number of layers included in the other dam upper layer. For example, the number of layers included in the first dam upper layer UA1 may be greater than the number of layers included in the second dam upper layer UA2, and the number of layers included in the second dam upper layer UA2 may be greater than the number of layers included in the third dam upper layer UA3 and/or the number of layers included in the fourth dam upper layer UA4.

On the other hand, the number of layers included in the dam upper layer of each dam illustrated in FIG. 4C and the types of layers included in each dam upper layer are not limited thereto. The height DH1a of the first dam upper layer UA1 may be determined to be greater than the height DH2a of the second dam upper layer UA2, the height DH2 of the second dam upper layer UA2 may be determined to be greater than the height DH3a of the third dam upper layer UA3 or the height DH4a of the fourth dam upper layer UA4, and the height DH3a of the third dam upper layer UA3 may be determined to be greater than or equal to the height DH4a of the fourth dam upper layer UA4.

Although not illustrated, the height DH1 of the first dam DAM1 may be formed to be greater than the heights of the other dams, and the height DH1 of the first dam DAM1, the height DH2 of the second dam DAM2, and the height DH3 of the third dam DAM3 may sequentially decrease. In addition, the height DH3 of the third dam DAM3 may be less than the height DH4 of the fourth dam DAM4. In this case, the third dam DAM3 and the fourth dam DAM4 may control the flow range of an organic material for forming the organic encapsulation layer 520 by interfering with the flow of an organic material for forming the organic encapsulation layer 520, or the second dam DAM2 may determine the range of the organic encapsulation layer 520.

In the above case, FIG. 4C illustrates that the thickness of the first-sixth dam upper layer UA1-6 is different from the thickness of the first-seventh dam upper layer UA1-7, but the disclosure is not limited thereto. The thickness of the first-sixth dam upper layer UA1-6 may be equal to the thickness of the first-seventh dam upper layer UA1-7. In addition, FIG. 4C illustrates that the thickness of the first-sixth dam upper layer UA1-6 is different from the thickness of the second-fourth dam upper layer UA2-4, but the disclosure is not limited thereto. The thickness of the first-sixth dam upper layer UA1-6 may be equal to the thickness of the second-fourth dam upper layer UA2-4. FIG. 4C illustrates that the thickness of the first inorganic encapsulation layer 510 is different from the thickness of the second-fourth dam upper layer UA2-4, but the disclosure is not limited thereto. The thickness of the first inorganic encapsulation layer 510 may be equal to the thickness of the second-fourth dam upper layer UA2-4. In this case, the thickness of one of the first-sixth dam upper layer UA1-6, the first-seventh dam upper layer UA1-7, the second-fourth dam upper layer UA2-4, and the first inorganic encapsulation layer 510 may be different from or equal to the thickness of another of the first-sixth dam upper layer UA1-6, the first-seventh dam upper layer UA1-7, the second-fourth dam upper layer UA2-4, and the first inorganic encapsulation layer 510.

The first inorganic encapsulation layer 510, the organic encapsulation layer 520, and the second inorganic encapsulation layer 530 may be sequentially arranged at the upper portion of the dam portion DAM. In this case, the first inorganic encapsulation layer 510 disposed at the upper portion of the dam portion DAM may include the same material as that of the first-first inorganic encapsulation layer 511, the first-second inorganic encapsulation layer 512, and/or the first-third inorganic encapsulation layer 513 illustrated in FIG. 4A. At this time, the dam portion DAM may reduce the speed of the flow of an organic material of the organic encapsulation layer 520 or limit the range in which the organic encapsulation layer 520 is disposed. Hereinafter, for convenience of explanation, a case where the first inorganic encapsulation layer 510 disposed in the dam portion DAM include the same material as that of the first-third inorganic encapsulation layer 513 will be described in detail.

FIG. 4D is a cross-sectional view schematically illustrating a dam portion of a display panel, according to another embodiment.

Referring to FIG. 4D, a first dam upper layer UA1 of a first dam (not shown), a second dam upper layer UA2 of a second dam (not shown), a third dam upper layer UA3 of a third dam (not shown), and a fourth dam upper layer UA4 of a fourth dam (not shown) may include materials that are identical to or similar to those described with reference to FIG. 4C.

The first dam upper layer UA1 of the first dam may include a first-first dam upper layer UA1-1, a first-second dam upper layer UA1-2, a first-third dam upper layer UA1-3, and a first-fourth dam upper layer UA1-4. In addition, the second dam upper layer UA2 of the second dam may include a second-first dam upper layer UA2-1, a second-second dam upper layer UA2-2 and a second-third dam upper layer UA2-3.

In the above case, the first-first dam upper layer UA1-1, the first-second dam upper layer UA1-2, the first-third dam upper layer UA1-3, and the first-fourth dam upper layer UA1-4 may be sequentially stacked in this stated order. One of the first-first dam upper layer UA1-1, the first-second dam upper layer UA1-2, the first-third dam upper layer UA1-3, and the first-fourth dam upper layer UA1-4 may be disposed only on the upper surface of another of the first dam base layer (not shown), the first-first dam upper layer UA1-1, the first-second dam upper layer UA1-2, the first-third dam upper layer UA1-3, and the first-fourth dam upper layer UA1-4, which are disposed below one of the first-first dam upper layer UA1-1, the first-second dam upper layer UA1-2, the first-third dam upper layer UA1-3, and the first-fourth dam upper layer UA1-4. In addition, the second-first dam upper layer UA2-1 may be disposed only on the upper surface of the second dam base layer (not shown), and the second-second dam upper layer UA2-2 may be disposed only on the upper surface of the second-first dam upper layer UA2-1.

The third dam upper layer UA3 may be disposed only on the upper surface of the third dam base layer (not shown), and the fourth dam upper layer UA4 may be disposed only on the upper surface of the fourth dam base layer (not shown).

The number and materials of the layers forming the first dam upper layer UA1 are not limited to the above examples. The height of the first dam upper layer UA1 may be determined to be greater than the height of other dam upper layers, or the height of the first dam may be determined to be greater than the height of other dams. In addition, the number and materials of the layers forming the second dam upper layer UA2 are not limited to the above examples. The height of the second dam upper layer UA2 may be determined to be greater than the height of the third dam upper layer UA3 and/or the height of the fourth dam upper layer UA4, or the height of the second dam may be determined to be greater than the height of the third dam and/or the height of the fourth dam. In addition, the number and materials of the layers forming the third dam upper layer UA3 or the fourth dam upper layer UA4 may be determined so that the height of the third dam upper layer UA3 is greater than or equal to the height of the fourth dam upper layer UA4.

FIGS. 5A to 5L are cross-sectional views schematically illustrating a method of manufacturing a display panel, according to an embodiment. Hereinafter, the same reference numerals as those in FIGS. 4A and 4C denote the same members.

Referring to FIG. 5A, a buffer layer 101, a gate insulating layer 103, a first interlayer insulating layer 105, a first sub-pixel circuit PC1, a second sub-pixel circuit PC2, a third sub-pixel circuit (not shown), a second interlayer insulating layer 107, a first organic layer 109, and a second organic layer 111 may be disposed on a substrate 100. At this time, a first dam base layer BA1, a second dam base layer BA2, a third dam base layer BA3, and a fourth dam base layer BA4 may also be disposed on the substrate 100 in a peripheral area PA. A first-first dam base layer BA1-1, a second-first dam base layer BA2-1, the third dam base layer BA3, and the fourth dam base layer BA4 may be patterned to be spaced apart from each other, and may be arranged to surround at least a portion of a circumference of a display area DA. At this time, the first-first dam base layer BA1-1, the second-first dam base layer BA2-1, the third dam base layer BA3, and the fourth dam base layer BA4 may be formed simultaneously when the first organic layer 109 is formed. For convenience of explanation, a case where the first-first dam base layer BA1-1, the second-first dam base layer BA2-1, the third dam base layer BA3, and the fourth dam base layer BA4 may each be arranged in a closed-loop shape surrounding the display area DA and the first-first dam base layer BA1-1, the second-first dam base layer BA2-1, the third dam base layer BA3, and the fourth dam base layer BA4 are arranged to be sequentially closer to each other in the display area DA will be described in detail. The first-second dam base layer BA1-2 may be disposed on the first-first dam base layer BA1-1, and the second-second dam base layer BA2-2 may be disposed on the second-first dam base layer BA2-1. In this case, the first-second dam base layer BA1-2 and the second-second dam base layer BA2-2 may be formed simultaneously when the second organic layer 111 is formed.

A first electrode layer 210a may be formed on the second organic layer 111. In this case, the first electrode layer 210a may be disposed in the entire display area DA and at least a portion of the peripheral area PA. A first photoresist PR1 may be disposed on the first electrode layer 210a. In this case, the first photoresist PR1 may be disposed only in a certain area through light exposure and development processes. For example, the first photoresist PR1 may include a first-first photoresist PR1-1 and a first-second photoresist PR1-2 spaced apart from each other on the display area DA. The first-second photoresist PR1-2 may be arranged in the first dam DAM1 of the dam portion DAM shown in FIG. 4C.

At this time, FIG. 5A illustrates that the first-second photoresist PR1-2 is arranged in an area where the first dam base layer BA1 is arranged, but the disclosure is not limited thereto. The first-second photoresist PR1-2 may be arranged in at least one of the dams. Hereinafter, for convenience, a case where the first-second photoresist PR1-2 is disposed only on the first dam base layer BA1 will be described in detail.

After the first photoresist PR1 is disposed as described above, a portion of the first electrode layer 210a on which the first photoresist PR1 is not disposed may be removed through dry etching or wet etching. That is, a portion of the first electrode layer 210a between the adjacent first-first photoresists PR1-1 and a portion of the first electrode layer 210a between the first-second photoresist PR1-2 and the first-first photoresist PR1-1 may be removed. Thereafter, the first photoresist PR1 may be removed.

Referring to FIG. 5B and in conjunction with FIGS. 4A and 5A, a first-first electrode 211, a first-second electrode 212, a first-third electrode 213, and a first-first dam upper layer UA1-1 may be formed by removing a portion of the first electrode layer 210a. In this case, the first-first electrode 211, the first-second electrode 212, the first-third electrode 213, and the first-first dam upper layer UA1-1 may include the same material as each other.

A first base material layer 113a may be formed on the second organic layer 111, the first-first electrode 211, the first-second electrode 212, the first-third electrode 213, the first-first dam upper layer UA1-1, the second dam base layer BA2, the third dam base layer BA3, and the fourth dam base layer BA4. The first base material layer 113a may include the same material as those of the insulating layers 1131, 1132, and 1133.

Second photoresists PR2 spaced apart from each other may be disposed on the first base material layer 113a through light exposure and development processes. In this case, the second photoresist PR2 may include a second-first photoresist PR2-1 and a second-second photoresist PR2-2 spaced apart from each other. The second-first photoresist PR2-1 may be arranged to correspond to the first-first electrode 211, the first-second electrode 212, and the first-third electrode 213. In addition, the second-second photoresist PR2-2 may be arranged to correspond to the first-first dam upper layer UA1-1. Thereafter, the first base material layer 113a in the area where the second photoresist PR2 is not arranged may be removed by supplying an etchant or plasma. In this case, the first base material layers 113a may be spaced apart from each other to correspond to the first-first electrode 211, the first-second electrode 212, the first-third electrode 213, and the first-first dam upper layer UA1-1. Thereafter, the second photoresist PR2 may be removed.

Referring to FIG. 5C and in conjunction with FIGS. 4A and 5B, after the first base material layer 113a is etched, a first-first base material layer 1131a, a first-second base material layer 1132a, and a first-third base material layer (not shown), which are a portion of the first base material layer 113a, may be respectively disposed on the first-first electrode 211, the first-second electrode 212, and the first-third electrode 213. In addition, a portion of the first base material layer 113a may remain on the first-first dam upper layer UA1-1 and become the first-second dam upper layer UA1-2 formed of the same material as those of the insulating layers 1131, 1132, and 1133.

A second base material layer 310a may be formed in at least a portion of the display area DA and the peripheral area PA. The second base material layer 310a may include the same material as that of the protective layer 310. The second base material layer 310a may be arranged similarly to the first base material layer 113a described with reference to FIG. 5B.

A third photoresist PR3 may be disposed on the second base material layer 310a through light exposure and development processes. The third photoresist PR3 may include a third-first photoresist PR3-1 disposed to cover the entire display area DA and a portion of the peripheral area PA, and a third-second photoresist PR3-2 disposed to cover the first-second dam upper layer UA1-2, the second-second dam base layer BA2-2, the third dam base layer BA3, and the fourth dam base layer BA4.

A portion of the second base material layer 310a, which is not covered by the third photoresist PR3, may be removed by supplying an etchant or plasma onto the third photoresist PR3. In this case, a first connection line 1620 may be exposed to the outside. Thereafter, the third photoresist PR3 may be removed.

In the above case, the first-third dam upper layer UA1-3 may be disposed on the first-second dam upper layer UA1-2, and the second-first dam upper layer UA2-1 may be disposed on the second-second dam base layer BA2-2. In addition, the third dam upper layer UA3 may be disposed on the third dam base layer BA3, and the fourth dam upper layer UA4 may be disposed on the fourth dam base layer BA4. The first-third dam upper layer UA1-3, the second-first dam upper layer UA2-1, the third dam upper layer UA3, and the fourth dam upper layer UA4 may include the same material as that of the second base material layer 310a.

Referring to FIG. 5D, a third base material layer 321a and a fourth base material layer 322a may be sequentially disposed on the second base material layer 310a. The third base material layer 321a may form a first metal layer 321 shown in FIG. 4A and the first-fourth dam upper layer UA1-4 and the second-second dam upper layer UA2-1 shown in FIG. 4C, and the fourth base material layer 322a may form a second metal layer 323 shown in FIG. 4A and the first-fifth dam upper layer UA1-5 and the second-third dam upper layer UA2-3. In this case, the third base material layer 321a and the fourth base material layer 322a may be arranged in the entire display area DA and a portion of the peripheral area PA. In the above case, the third base material layer 321a or the fourth base material layer 322a may be connected to the first connection line 1620. Hereinafter, for convenience of explanation, a case where the third base material layer 321a is connected to the first connection line 1620 will be described in detail.

A fourth photoresist PR4 may be disposed on the fourth base material layer 322a through light exposure and development processes. The fourth photoresist PR4 may include a first opening PR4-OP in a portion corresponding to the first-first electrode 211. The fourth photoresist PR4 may cover a portion of the fourth base material layer 322a such that the fourth base material layer 322a is not exposed, except for a portion above the first-first electrode 211.

Referring to FIG. 5E and in conjunction with FIGS. 4A and 5D, openings may be formed in the third base material layer 321a and the fourth base material layer 322a by sequentially removing a portion of the fourth base material layer 322a and a portion of the third base material layer 321a through the first opening PR4-OP. A portion of the fourth base material layer 322a and a portion of the third base material layer 321a may be removed by dry etching. During the etching process, the insulating layers 1131, 1132, and 1133 and the protective layer 310 may protect the first-first electrode 211 therebelow.

Undercut-shaped openings may be formed in the third base material layer 321a and the fourth base material layer 322a by using the fourth photoresist PR4 as a mask. In some embodiments, the undercut-shaped openings may be formed in the third base material layer 321a and the fourth base material layer 322a through wet etching.

The insulating layers 1131, 1132, and 1133 and the protective layer 310 arranged in the openings of the third base material layer 321a and the fourth base material layer 322a may be partially removed by using the fourth photoresist PR4 as a mask. In this case, the insulating layers 1131, 1132, and 1133 may be removed through dry etching, and a portion of the protective layer 310 may be removed through wet etching. In this case, the first-first electrode 211 may be exposed through the first sub-pixel opening OP1 of the third base material layer 321a, the fourth base material layer 322a, the insulating layers 1131, 1132, and 1133, and the protective layer 310.

Thereafter, the fourth photoresist PR4 may be removed.

Referring to FIG. 5F and in conjunction with FIG. 4A, a fifth photoresist PR5 may be disposed on the fourth base material layer 322a. At this time, the fifth photoresist PR5 may expose, to the outside, the third base material layer 321a and the fourth base material layer 322a disposed on the upper surfaces of the third dam upper layer UA3 and the fourth dam upper layer UA4 through a fifth-first photoresist PR5-1 and a fifth-second photoresist PR5-2 separated from each other through light exposure and development processes. The fifth-first photoresist PR5-1 may cover the entire display area DA and a portion of the peripheral area PA, and the fifth-second photoresist PR5-2 may cover another portion of the peripheral area PA. Thereafter, the third base material layer 321a and the fourth base material layer 322a covering the third dam upper layer UA3 and the fourth dam upper layer UA4 may be removed through dry etching or wet etching.

In the above case, the first-fourth dam upper layer UA1-4 and the first-fifth dam upper layer UA1-5 may be sequentially disposed on the first-third dam upper layer UA1-3, and the second-second dam upper layer UA2-2 and the second-third dam upper layer UA2-3 may be sequentially disposed on the second-first dam upper layer UA2-1. The first-fourth dam upper layer UA1-4 and the second-second dam upper layer UA2-2 may include the same material as that of the third base material layer 321a, and the first-fifth dam upper layer UA1-5 and the second-third dam upper layer UA2-3 may include the same material as that of the fourth base material layer 322a.

The fifth photoresist PR5 may be removed after the above process.

Referring to FIG. 5G and in conjunction with FIG. 4A, a fifth base material layer 2201a, a sixth base material layer 231a, and a seventh base material layer 511a may be arranged in the display area DA. At least one of the fifth base material layer 2201a, the sixth base material layer 231a, and the seventh base material layer 511a may be arranged in the display area DA or may be arranged in the display area DA and the peripheral area PA. The fifth base material layer 2201a, the sixth base material layer 231a, and the seventh base material layer 511a may include the same materials as those of the first intermediate layer 2201, the second-first electrode 231, and the first-first inorganic encapsulation layer 511, respectively. For convenience of explanation, the fifth base material layer 2201a and the sixth base material layer 231a may be disposed above the upper surface of the second organic layer 111 arranged in the display area DA and the peripheral area PA, and the seventh base material layer 511a may be arranged in the display area DA and the peripheral area PA.

A sixth photoresist PR6 may be arranged in the display area DA and the peripheral area PA. The sixth photoresist PR6 may include a sixth-first photoresist PR6-1 disposed to cover the first sub-pixel opening OP1, and a sixth-second photoresist PR6-2 disposed on the seventh base material layer 511a of the first-fifth dam upper layer UA1-5 and the second-third dam upper layer UA2-3.

Referring to FIG. 5H and in conjunction with FIG. 5G, portions of the fifth base material layer 2201a, the sixth base material layer 231a, and the seventh base material layer 511a, which are not shielded by the sixth photoresist PR6, may be removed through dry etching or wet etching. In this case, an etching rate, an etching depth, and the like may be controlled according to the number of layers arranged in the portions to be removed. In another embodiment, all areas except for the display area DA may be coated with a photoresist, the fifth base material layer 2201a, the sixth base material layer 231a, and the seventh base material layer 511a arranged in the display area DA, excluding the layer arranged in the first sub-pixel opening OP1, may be removed, and then, only the seventh base material layer 511a arranged in a portion of the peripheral area PA may be removed.

When the above process is completed, a first-sixth dam upper layer UA1-6 may be disposed on the first-fifth dam upper layer UA1-5. In addition, a second-fourth dam upper layer UA2-4 may be disposed on the second-third dam upper layer UA2-3. In this case, the first-sixth dam upper layer UA1-6 and the second-fourth dam upper layer UA2-4 may include the same material as that of the first-first inorganic encapsulation layer 511. Thereafter, the sixth photoresist PR6 may be removed.

Referring to FIGS. 51 and 5J, after the first sub-pixel P1 (see FIG. 4A) is formed, a seventh photoresist PR7 having a second opening PR7-OP located at a position corresponding to the first-second electrodes 212 may be disposed on the fourth base material layer 322a. Thereafter, a second sub-pixel opening OP2 may be formed by a method similar to the method of forming the first sub-pixel opening OP1 (e.g., see FIG. 5H).

Referring to FIG. 5K and in conjunction with FIG. 4A, an eighth base material layer 2202a, a ninth base material layer 232a, and a tenth base material layer 512a may be arranged in at least a portion of the display area DA and the peripheral area PA. In this case, the eighth base material layer 2202a, the ninth base material layer 232a, and the tenth base material layer 512a may include the same materials as those of the second intermediate layer 2202, the second-second electrode 232, and the first-second inorganic encapsulation layer 512, respectively. After an eighth photoresist PR8 including an eighth-first photoresist PR8-1 and an eighth-second photoresist PR8-2 may be disposed on at least one of the eighth base material layer 2202a, the ninth base material layer 232a, or the tenth base material layer 512a, a second intermediate layer 2202, a second-second electrode 232, and a first-second inorganic encapsulation layer 512 may be formed in the second sub-pixel opening OP2, and a first-seventh dam upper layer (see the first-seventh dam upper layer UA1-7 of FIG. 5L) may be formed on the first-sixth dam upper layer UA1-6. In this case, the second intermediate layer 2202, the second-second electrode 232, the first-second inorganic encapsulation layer 512, and the first-seventh dam upper layer UA1-7 may be formed in a method similar to the method of forming the first intermediate layer 2201, the second-first electrode 231, the first-first inorganic encapsulation layer 511, and the first-sixth dam upper layer UA1-6, which has been described with reference to FIGS. 5G and 5H.

Thereafter, the eighth photoresist PR8 may be removed.

Referring to FIG. 5L and in conjunction with FIG. 4A, an eleventh base material layer 2203a, a twelfth base material layer 233a, and a thirteenth base material layer 513a may be arranged in at least a portion of the display area DA and the peripheral area PA. In this case, the eleventh base material layer 2203a, the twelfth base material layer 233a, and the thirteenth base material layer 513a may respectively include the same materials as those of the third intermediate layer 2203, the second-third electrode 233, and the first-third inorganic encapsulation layer 513. The eleventh base material layer 2203a and the twelfth base material layer 233a may not be arranged in the peripheral area PA where the dam portion is arranged. In addition, the thirteenth base material layer 513a may be arranged both in the display area DA and in the peripheral area PA where the dam portion is arranged. A third sub-pixel opening OP3 may be formed by a method similar to the method of forming the first sub-pixel opening OP1 (e.g., see FIG. 5H) and a third intermediate layer 2203, a second-third electrode 233, and a first-third inorganic encapsulation layer 513 may be arranged in the third sub-pixel opening OP3 by a method similar to the method of forming the first intermediate layer 2201, the second-first electrode 231, the first-first inorganic encapsulation layer 511, and the first-sixth dam upper layer UA1-6, which has been described with reference to FIGS. 5G and 5H.

A ninth photoresist PR9 including a ninth-first photoresist PR9-1 and a ninth-second photoresist PR9-2 may be disposed on the thirteenth base material layer 513a, and dry etching or wet etching may be performed thereon. Thereafter, the ninth photoresist PR9 may be removed.

An organic encapsulation layer 520 may be disposed on the first inorganic encapsulation layer 510. In addition, a second inorganic encapsulation layer 530 may be disposed on the organic encapsulation layer 520. In this case, the second inorganic encapsulation layer 530 may be disposed to completely cover the display area DA and the peripheral area PA where the dam portion DAM is arranged.

When the above process is completed, the display area DA and the peripheral area PA may have shapes identical to or similar to those illustrated in FIGS. 4A to 4C.

An organic material for forming the organic encapsulation layer 520 may be supplied to the display area DA through an inkjet nozzle. In this case, an organic material for forming the organic encapsulation layer 520 may flow from the display area DA to the peripheral area PA. At this time, the dam portion DAM may control the flow range of an organic material for forming the organic encapsulation layer 520 through the difference in height of each dam.

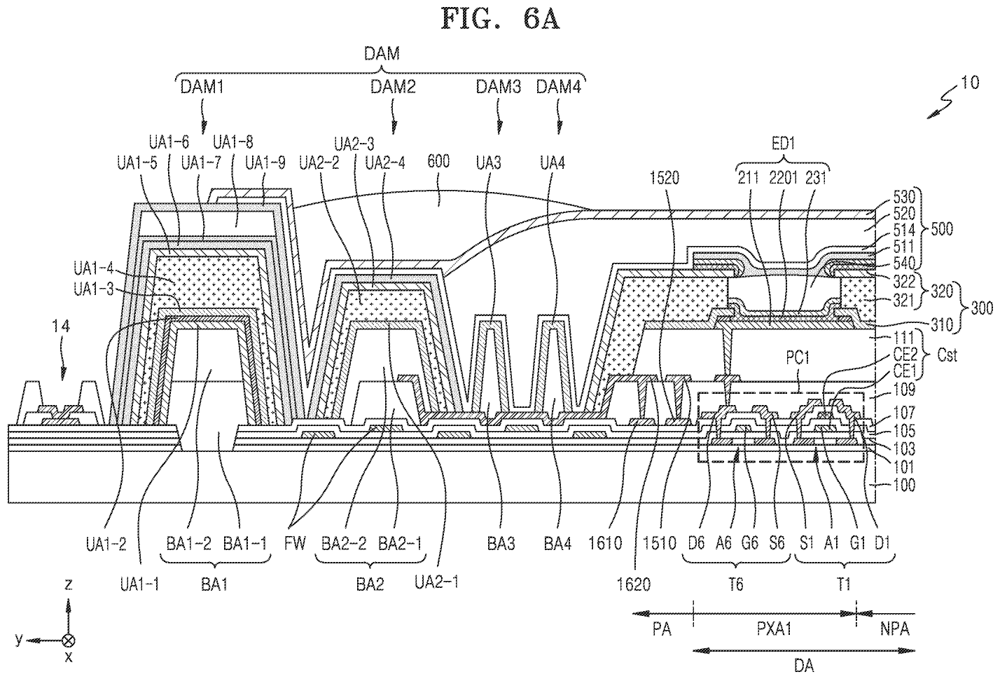

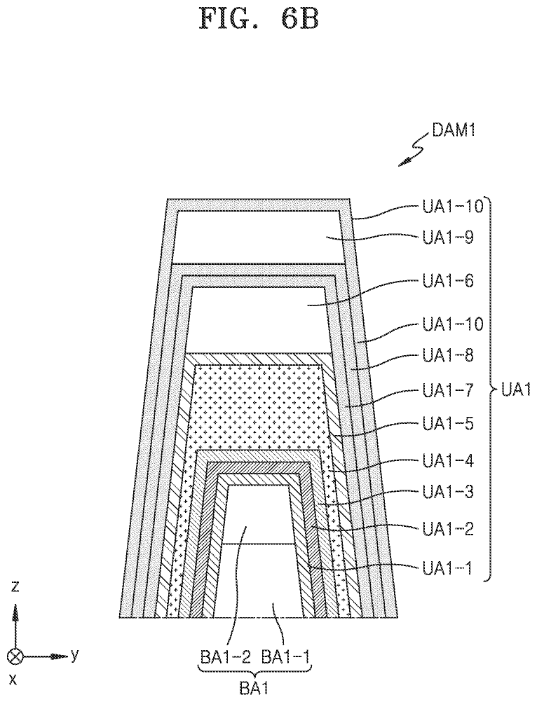

FIG. 6A is a cross-sectional view schematically illustrating a portion of a display panel 10, according to another embodiment. Hereinafter, the same reference numerals as those in FIGS. 4A and 4C denote the same or similar members.

Referring to FIG. 6A and in conjunction with FIG. 4A, the display panel 10 may include a substrate 100, a buffer layer 101, a gate insulating layer 103, a first sub-pixel circuit PC1, a second sub-pixel circuit PC2, a third sub-pixel circuit PC3, a first interlayer insulating layer 105, a second interlayer insulating layer 107, source electrodes S1 and S6, drain electrodes D1 and D6, a first organic layer 109, a connection electrode CM, a second organic layer 111, a first electrode 210 including a first-first electrode 211, a first-second electrode 212, and a first-third electrode 213, a protective layer 310, insulation layers 1131, 1132, and 1133, a bank layer 320 including a first metal layer 321 and a second metal layer 323, an intermediate layer 220 including a first intermediate layer 2201, a second intermediate layer 2202, and a third intermediate layer 2203, a second electrode 230 including a second-first electrode 231, a second-second electrode 232, and a second-third electrode 233, a first inorganic encapsulation layer 510 including a first-first inorganic encapsulation layer 511, a first-second inorganic encapsulation layer 512, and a first-third inorganic encapsulation layer 513, a planarization layer 540, an additional inorganic encapsulation layer 514, an organic encapsulation layer 520, a second inorganic encapsulation layer 530, a common power supply line (not shown), a first bridge line 1610, a first connection line 1620, a driving voltage supply line (not shown), a second bridge line 1510, a second connection line 1520, a dam portion DAM, and a terminal 14.

The first sub-pixel circuit PC1, the second sub-pixel circuit PC2, and the third sub-pixel circuit PC3 may be disposed on the buffer layer 101. The first sub-pixel circuit PC1, the second sub-pixel circuit PC2, and the third sub-pixel circuit PC3 may each include a plurality of transistors and a storage capacitor, as illustrated in FIG. 3A or 3B.

A first transistor T1 may include a first semiconductor layer A1 on the buffer layer 101, and a first gate electrode G1 overlapping a channel region of the first semiconductor layer A1. A sixth transistor T6 may include a sixth semiconductor layer A6 on the buffer layer 101, and a sixth gate electrode G6 overlapping a channel region of the sixth semiconductor layer A6. A storage capacitor Cst may include a lower electrode CE1 and an upper electrode CE2 overlapping each other.

Because the display panel 10 is similar to the display panel 10 described with reference to FIGS. 4A to 4C, a detailed description is given focusing on differences from the display panel 10 illustrated in FIGS. 4A to 4C.

The planarization layer 540 may be inserted into each sub-pixel opening. In this case, the planarization layer 540 may include a polymer-based material. The polymer-based material may include acrylic-based resin, epoxy-based resin, polyimide, polyethylene, and the like. The refractive index of the planarization layer 540 may be greater than the refractive index of the first inorganic encapsulation layer 510. For example, the refractive index of the planarization layer 540 may be greater than or equal to about 1.6. The refractive index of the planarization layer 540 may be about 1.6 to about 1.9. The planarization layer 540 may further include dispersed particles for high refractive index. For example, metal oxide particles, such as zinc oxide (ZnOₓ, such as ZnO or ZnO₂), titanium oxide (TiO₂), zirconium oxide (ZrO₂), or barium titanate (BaTiO₃), may be dispersed in the planarization layer 540.

The additional inorganic encapsulation layer 514 may be disposed to cover an entire display area DA and a portion of a peripheral area PA. The additional inorganic encapsulation layer 514 may be disposed to completely cover a fourth dam upper layer UA4, a third dam upper layer UA3, and a second dam upper layer UA2, and the end of the additional inorganic encapsulation layer 514 may be disposed on a first dam upper layer UA1 of a first dam DAM1. The additional inorganic encapsulation layer 514 may include the same material as that of the first inorganic encapsulation layer 510 or the second inorganic encapsulation layer 530.

The organic encapsulation layer 520 may be disposed on the additional inorganic encapsulation layer 514. In addition, the second inorganic encapsulation layer 530 may be disposed on the organic encapsulation layer 520. In the above case, the dam portion DAM may limit the movement path of the organic material for forming the organic encapsulation layer 520 when the organic encapsulation layer 520 disposed on the display panel 10 is formed, thereby preventing the organic material for forming the organic encapsulation layer 520 from moving to the terminal 14 or the like or from flowing to the edge of the substrate 100. The dam portion DAM may include at least one of the first dam DAM1, a second dam DAM2, a third dam DAM3, and a fourth dam DAM4. The first dam DAM1, the second dam DAM2, the third dam DAM3, and the fourth dam DAM4 may be the same as or similar to those described with reference to FIG. 4C.

An upper planarization layer 600 (shown, e.g., in FIG. 6A), which includes a separate organic material, may be disposed on the dam portion DAM. In this case, the upper planarization layer 600 may planarize the upper surface of the second inorganic encapsulation layer 530. The upper planarization layer 600 may include a material identical to or similar to that of the organic encapsulation layer 520. Similar to the organic encapsulation layer 520, an organic material for forming the upper planarization layer 600 may be supplied through an inkjet nozzle and thereby the upper planarization layer 600 is disposed on the upper surface of the dam portion DAM. At this time, the first dam DAM1, the second dam DAM2, the third dam DAM3, and the fourth dam DAM4 may slow down the flow of the organic material for forming the upper planarization layer 600 and may limit the spread range. This may reduce that the upper planarization layer 600 exceeds a specified range. In particular, because the first dam DAM1 is the highest, the first dam DAM1 may prevent the upper planarization layer 600 from passing over to the terminal 14.

In the above case, FIG. 6A illustrates that the thickness of the first-sixth dam upper layer UA1-6 is different from the thickness of the first-seventh dam upper layer UA1-7, but the disclosure is not limited thereto. The thickness of the first-sixth dam upper layer UA1-6 may be equal to the thickness of the first-seventh dam upper layer UA1-7. In addition, FIG. 6A illustrates that the thickness of the first-ninth dam upper layer UA1-9 is different from the thickness of the first-seventh dam upper layer UA1-7, but the disclosure is not limited thereto. The thickness of the first-ninth dam upper layer UA1-9 may be equal to the thickness of the first-seventh dam upper layer UA1-7. FIG. 6A illustrates that the thickness of the first-seventh dam upper layer UA1-7 is different from the thickness of the additional inorganic encapsulation layer 514, but the disclosure is not limited thereto. The thickness of the first-seventh dam upper layer UA1-7 may be equal to the thickness of the additional inorganic encapsulation layer 514. In addition, FIG. 6A illustrates that the thickness of the first-sixth dam upper layer UA1-6 is different from the thickness of the additional inorganic encapsulation layer 514, but the disclosure is not limited thereto. The thickness of the first-sixth dam upper layer UA1-6 may be equal to the thickness of the additional inorganic encapsulation layer 514. In the above case, the thickness of one of the first-sixth dam upper layer UA1-6, the first-seventh dam upper layer UA1-7, the first-ninth dam upper layer UA1-9, and the additional inorganic encapsulation layer 514 may be equal to or different from the thickness of another of the first-sixth dam upper layer UA1-6, the first-seventh dam upper layer UA1-7, the first-ninth dam upper layer UA1-9, and the additional inorganic encapsulation layer 514.

FIG. 6B is a cross-sectional view schematically illustrating the first dam DAM1 of FIG. 6A.

Referring to FIG. 6B, the first dam DAM1 may include a first dam base layer BA1 and a first dam upper layer UA1. In this case, the first dam base layer BA1 may include a first-first dam base layer BA1-1 and a first-second dam base layer BA1-2. Because the first-first dam base layer BA1-1 and the first-second dam base layer BA1-2 are the same as or similar to those described with reference to FIG. 4C, a detailed description thereof is omitted.

The first dam upper layer UA1 may include a first-first dam upper layer UA1-1, a first-second dam upper layer UA1-2, a first-third dam upper layer UA1-3, a first-fourth dam upper layer UA1-4, a first-fifth dam upper layer UA1-5, a first-sixth dam upper layer UA1-6, a first-seventh dam upper layer UA1-7, a first-eighth dam upper layer UA1-8, a first-ninth dam upper layer UA1-9, and a first-tenth dam upper layer UA1-10, which are sequentially stacked on the upper surface of the first dam base layer BA1 in this stated order. Because the first-first dam upper layer UA1-1, the first-second dam upper layer UA1-2, the first-third dam upper layer UA1-3, the first-fourth dam upper layer UA1-4, and the first-fifth dam upper layer UA1-5 are the same as or similar to those described with reference to FIG. 4C, a detailed description thereof is omitted.

The first-sixth dam upper layer UA1-6 may be disposed on the first-fifth dam upper layer UA1-5 when the planarization layer 540 illustrated in FIG. 6A is formed. The first-sixth dam upper layer UA1-6 may include the same material as that of the planarization layer 540. In this case, after the planarization layer 540 is disposed on each sub-pixel opening and the first-fifth dam upper layer UA1-5 or is disposed on both the display area DA and the dam portion DAM, a separate photoresist may be provided so that only the planarization layer 540 disposed on the sub-pixel opening and the first-fifth dam upper layers UA1-5 remains and the remaining portions thereof are removed.

The first-seventh dam upper layer UA1-7 may be disposed on the first-sixth dam upper layer UA1-6. In this case, the first-seventh dam upper layer UA1-7 may include the same material as that of the first-first inorganic encapsulation layer (not shown). In addition, the first-eighth dam upper layer UA1-8 may be disposed on the first-seventh dam upper layer UA1-7. In this case, the first-eighth dam upper layer UA1-8 may include the same material as that of the first-second inorganic encapsulation layer (not shown). In another embodiment, an additional dam upper layer (not shown) may be between the first-seventh dam upper layer UA1-7 and the first-eighth dam upper layer UA1-8. In this case, the additional dam upper layer may include the same material as that of the planarization layer (not shown) disposed to correspond to the second sub-pixel P2 described with reference to FIG. 4A.

The first-ninth dam upper layer UA1-9 may be disposed on the first-eighth dam upper layer UA1-8. The first-ninth dam upper layer UA1-9 may be formed when the planarization layer disposed to correspond to the third sub-pixel P3 of FIG. 4A is formed. The first-ninth dam upper layer UA1-9 may include the same material as that of the planarization layer.

The first-tenth dam upper layer UA1-10 may be disposed on the first-ninth dam upper layer UA1-9. The first-tenth dam upper layer UA1-10 may be formed when the first-third inorganic encapsulation layer (not shown in FIG. 6A) illustrated in FIG. 4A is formed. In this case, the first-tenth dam upper layer UA1-10 may include the same material as that of the first-third inorganic encapsulation layer. The method of forming the first-tenth dam upper layer UA1-10 may be the same as or similar to the method of forming the first-seventh dam upper layer UA1-7.

In an embodiment, one of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, the first-ninth dam upper layer UA1-9, and the first-tenth dam upper layer UA1-10 may be disposed to surround the outer surface of one of the first dam base layer BA1 (which is disposed below one of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, the first-ninth dam upper layer UA1-9, and the first-tenth dam upper layer UA1-10), the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, and the first-ninth dam upper layer UA1-9.

In another embodiment, one of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, the first-ninth dam upper layer UA1-9, and the first-tenth dam upper layer UA1-10 may be disposed only on the upper surface of one of the first dam base layer BA1 (which is disposed below one of the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, the first-ninth dam upper layer UA1-9, and the first-tenth dam upper layer UA1-10), the first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, the first-seventh dam upper layer UA1-7, the first-eighth dam upper layer UA1-8, and the first-ninth dam upper layer UA1-9.

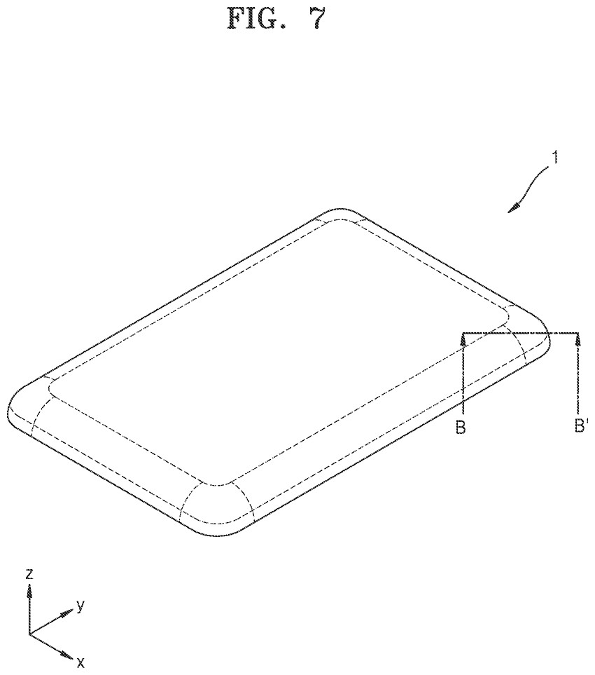

FIG. 7 is a perspective view schematically illustrating a display apparatus 1 according to another embodiment.

Referring to FIG. 7, the display apparatus 1 is configured to display a moving image or a still image. The display apparatus 1 may be a portable electronic apparatus, such as a mobile phone, a smartphone, a tablet personal computer, a mobile communication terminal, an electronic organizer, an e-book, a PMP, a navigation system, and a UMPC. In addition, the display apparatus 1 may be an electronic apparatus, such as a television, a laptop, a monitor, a billboard, and an loT device. Alternatively, the display apparatus 1 may be a wearable device, such as a smart watch, a watch phone, a glass-type display, or an HMD.

In an embodiment, the display apparatus 1 may have a rectangular shape in a plan view. In an alternative embodiment, the display apparatus 1 may have various shapes, such as other polygonal shapes (e.g., a triangular shape etc.), a circular shape, and an elliptical shape. In an embodiment, when the display apparatus 1 has a polygonal shape in a plan view, the polygon may have round corners. For convenience of explanation, a case where the display apparatus 1 has a rectangular shape with round corners in a plan view is mainly described.

The display apparatus 1 may have a short side in a first direction (e.g., the x direction or the −x direction) and a long side in a second direction (e.g., the y direction or the −y direction). In another embodiment, in the display apparatus 1, the length of the side in the first direction (e.g., the x direction or the −x direction) may be equal to the length of the side in the second direction (e.g., the y direction or the −y direction). In another embodiment, the display apparatus 1 may have a long side in the first direction (e.g., the x direction or the −x direction) and a short side in the second direction (e.g., the y direction or the −y direction). Each corner where the short side in the first direction (e.g., the x direction or the −x direction) meets the long side in the second direction (e.g., the y direction or the −y direction) may be round to have a certain curvature.

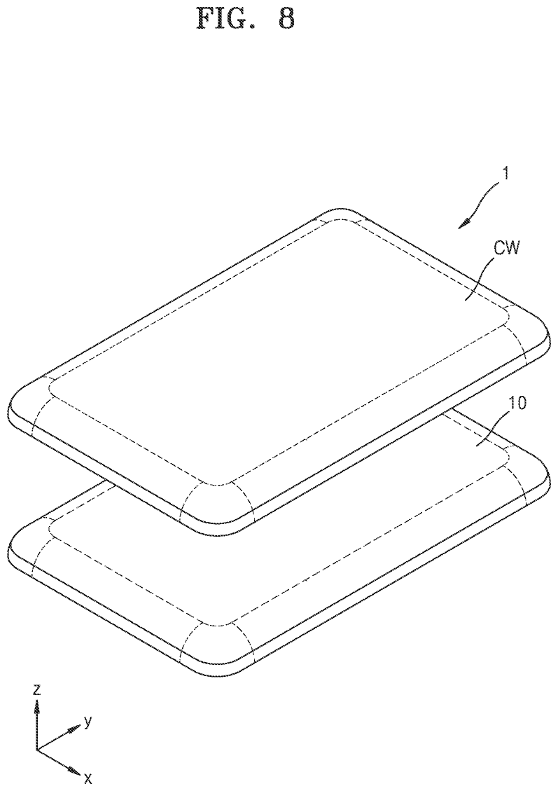

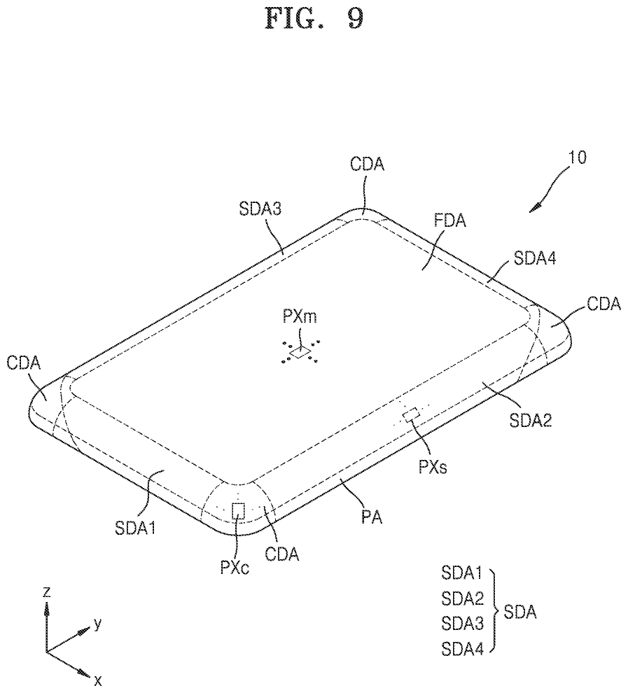

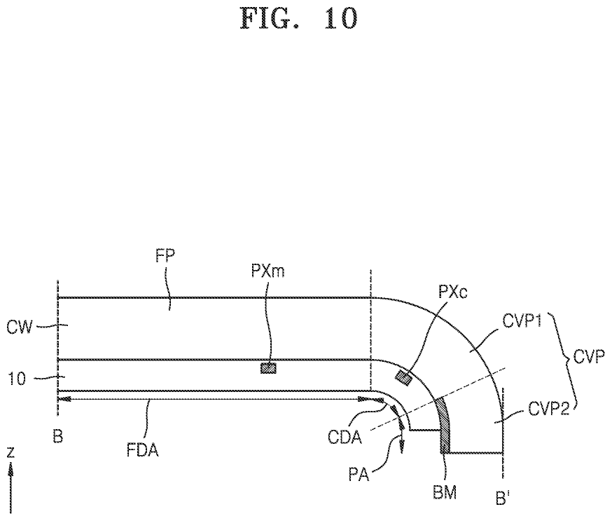

FIG. 8 is an exploded perspective view illustrating a portion of a display apparatus 1, according to another embodiment. FIG. 9 is a perspective view schematically illustrating a display panel of a display apparatus 1, according to another embodiment. FIG. 10 is a cross-sectional view of the display apparatus 1 of FIG. 7 taken along line B-B′ of FIG. 7.

Referring to FIGS. 8 to 10, the display apparatus 1 may include a display panel 10 and a cover window CW disposed on the display panel 10.

The display panel 10 may include a front display area FDA, a side display area SDA, and a corner display area CDA as a display area. The display apparatus 1 may include a peripheral area PA surrounding the display area.

The front display area FDA is an area disposed on a front portion of the display panel 10 and may be flat without bending. The front display area FDA may occupy most of the display area of the display panel 10, and thus, may provide most of an image. That is, the front display area FDA may be a main display area. The front display area FDA may include a short side in the x direction and a long side in the y direction, and each corner where the short side meets the long side may be rounded.

At least a portion of the side display area SDA may be bent to include a curved surface, and may extend outward from each side of the front display area FDA. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, and the fourth side display area SDA4 may be omitted.

The first side display area SDA1 may be an area that extends from a first side of the front display area FDA and is bent with a certain curvature. The first side display area SDA1 may extend from the lower side of the front display area FDA. The first side display area SDA1 may be an area disposed on the lower side of the display panel 10.

The second side display area SDA2 may be an area that extends from a second side of the front display area FDA and is bent with a certain curvature. The second side display area SDA2 may extend from the right side of the front display area FDA. The second side display area SDA2 may be an area disposed on the right side of the display panel 10.

The third side display area SDA3 may be an area that extends from a third side of the front display area FDA and is bent with a certain curvature. The third side display area SDA3 may extend from the left side of the front display area FDA. The third side display area SDA3 may be an area disposed on the left side of the display panel 10.

The fourth side display area SDA4 may be an area that extends from a fourth side of the front display area FDA and is bent with a certain curvature. The fourth side display area SDA4 may extend from the upper side of the front display area FDA. The fourth side display area SDA4 may be an area disposed on the upper side of the display panel 10.

The first to fourth side display areas SDA1, SDA2, SDA3, and SDA4 may each include a curved surface that is bent with a constant curvature. For example, the first side display area SDA1 and the fourth side display area SDA4 may each have a curved surface that is bent with respect to a bending axis extending in the x direction, and the second side display area SDA2 and the third side display area SDA3 may each have a curved surface that is bent with respect to a bending axis extending in the y direction. The curvatures of each of the first to fourth side display areas SDA1, SDA2, SDA3, and SDA4 may be equal to or different from each other.

The corner display area CDA may be an area that extends from the corner of the front display area FDA and is bent with a certain curvature. The corner display area CDA may be between the first to fourth side display areas SDA1 to SDA4. For example, the corner display area CDA may be between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Because the corner display area CDA is between the adjacent side display areas SDA having surfaces that curve in different directions, the corner display area CDA may include a curved surface that is bent to continuously connect the adjacent side display areas SDA to each other. In addition, when the curvatures of the adjacent side display areas SDA are different from each other, the curvature of the corner display area CDA may gradually change along the edge of the display apparatus 1. For example, when the curvature of the first side display area SDA1 is different from the curvature of the second side display area SDA2, the corner display area CDA between the first side display area SDA1 and the second side display area SDA2 may have a curvature that gradually changes.

The display panel 10 may provide images by using main sub-pixels PXm arranged in the front display area FDA, side sub-pixels PXs arranged in the side display area SDA, and corner sub-pixels PXc arranged in the corner display area CDA. Because the display panel 10 provides images to the side display area SDA and the corner display area CDA in addition to the front display area FDA, the proportion of the display area in the display apparatus 1 may increase. That is, in the display apparatus 1 having the same size, the area of the peripheral area PA may be reduced and the area of the display area may be increased.

The peripheral area PA may be disposed to completely or partially surround the periphery of the side display area SDA and the corner display area CDA. The peripheral area PA is an area where an image is not displayed, and various wirings and driving circuits may be arranged therein. A shield such as a light blocking member may be provided in the peripheral area PA so that members arranged in the peripheral area PA are not visually recognized.

Referring to FIG. 8, the cover window CW may be disposed on the front surface of the display panel 10. The ‘front surface’ of the display panel 10 may be defined as a surface facing a direction in which the display panel 10 provides an image.

The cover window CW may cover and protect the display panel 10. The cover window CW may have high transmittance in order to transmit light emitted from the display panel 10, and may have a small thickness in order to minimize the weight of the display apparatus 1. In addition, the cover window CW may have strong strength and hardness in order to protect the display panel 10 from external impact.

The cover window CW may include a transparent material. The cover window CW may include, for example, glass or plastic. When the cover window CW includes plastic, the cover window CW may be flexible. The cover window CW may include, for example, Ultra-Thin Glass (UTG®), the strength of which is strengthened by chemical strengthening or thermal strengthening. In another embodiment, the cover window CW may include UTG® and colorless polyimide (CPI). In an embodiment, the cover window CW may have a structure in which a flexible polymer layer is disposed on one surface of a glass substrate, or may include only a polymer layer.

In conjunction with FIGS. 8 and 10, the cover window CW may include a flat portion FP corresponding to the front display area FDA of the display panel 10, and a curved portion CVP corresponding to the side display area SDA and the corner display area CDA.

The flat portion FP of the cover window CW may be provided as a flat surface and may overlap the front display area FDA of the display panel 10. The curved portion CVP of the cover window CW may be provided as a curved surface. In this case, the curved portion CVP may have a constant curvature or a varying curvature. The curved portion CVP may include a first curved portion CVP1 and a second curved portion CVP2. The first curved portion CVP1 may be disposed to overlap the side display area SDA and the corner display area CDA of the display panel 10. The second curved portion CVP2 may be disposed to overlap the peripheral area PA of the display panel 10. The first curved portion CVP1 may be between the flat portion FP and the second curved portion CVP2.

A light blocking member BM may be arranged in a portion of the second curved portion CVP2 of the cover window CW. The light blocking member BM may cover a lower structure disposed therebelow and may be disposed to overlap the peripheral area PA of the display panel 10. The light blocking member BM may include a light blocking material. The light blocking member BM may include a resin including carbon nanotubes, and black dye (e.g., carbon black). Alternatively, the light blocking member BM may include nickel, aluminum, molybdenum, or any alloy thereof. The light blocking member BM may be applied by inkjet or bonded in the form of a film.

The display panel 10 may be disposed below the cover window CW. The cover window CW and the display panel 10 may be connected to each other through an adhesive member (not shown). The adhesive member may be an optically cleared adhesive (OCA) film or an optically cleared resin (OCR) film.

The display panel 10 may provide an image by using the main sub-pixels PXm arranged in the front display area FDA and the corner sub-pixels PXc arranged in the corner display area CDA. A lower protective film (not shown) may be further disposed below the display panel 10 so as to protect the display panel 10.

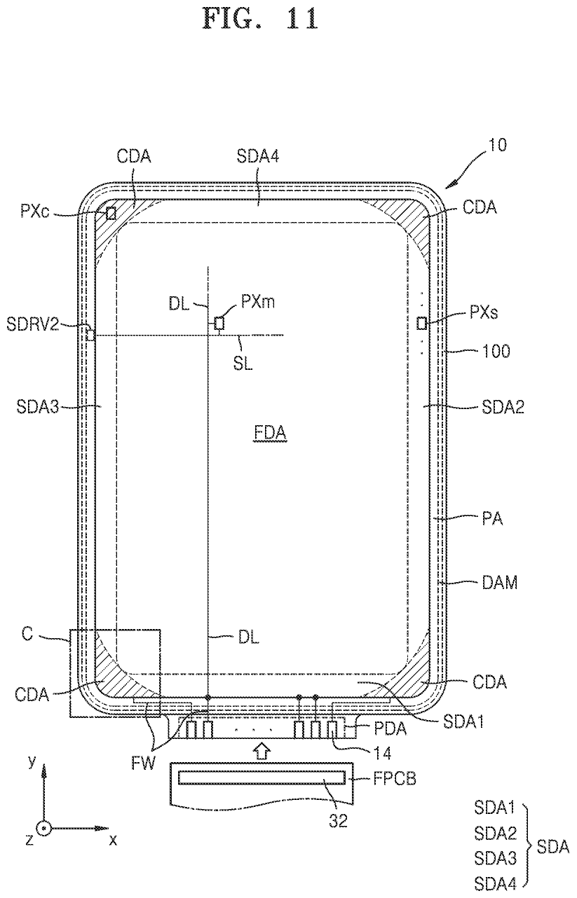

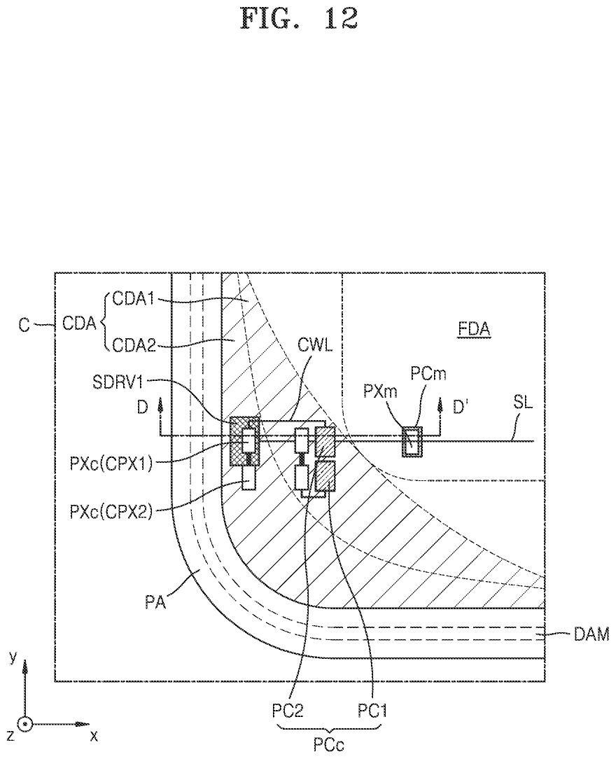

FIG. 11 is a plan view schematically illustrating a state in which the display panel 10 included in the display apparatus 1 of FIG. 7 is unfolded, according to an embodiment. FIG. 12 is an enlarged view of region C of FIG. 11.

Referring to FIGS. 11 and 12, various components constituting the display panel 10 may be disposed on a substrate 100. The substrate 100 may include a front display area FDA, a side display area SDA, a corner display area CDA, and a peripheral area PA.

A plurality of main sub-pixels PXm may be arranged in the front display area FDA. The main sub-pixels PXm may be configured to display a main image. A plurality of main sub-pixels PXm may be provided and may each emit red light, green light, blue light, or white light.

The side display area SDA may be disposed above or below the front display area FDA, or may be arranged on at least one of the left and right side of the front display area FDA. A plurality of side sub-pixels PXs may be arranged in the side display area SDA. The side sub-pixels PXs may be configured to display a side image. The side image may form one whole image together with the main image, or the side image may be an image independent of the main image.

The corner display area CDA may be arranged in an area extending from the corner of the front display area FDA. The corner display area CDA may be between two side display areas SDA. A plurality of corner sub-pixels PXc may be arranged in the corner display area CDA. The corner sub-pixels PXc may be configured to display a corner image. The corner image may form one whole image together with the main image and the side image, or the corner image may be an image independent of the main image.

The corner display area CDA may include a first corner display area CDA1 and a second corner display area CDA2. The second corner display area CDA2 is an area extending from the first corner display area CDA1. The second corner display area CDA2 may be arranged to be closer to the edge of the substrate 100 than the first corner display area CDA1. The first corner display area CDA1 may be between the second corner display area CDA2 and the front display area FDA.

In addition to the corner sub-pixel PXc, a driving circuit SDRV1 may be arranged in the second corner display area CDA2. The driving circuit SDRV1 may be configured to provide scan signals for driving the main sub-pixel PXm and corner sub-pixels PXc respectively arranged in the front display area FDA and the corner display area CDA. In some embodiments, the driving circuit SDRV1 may be simultaneously connected to a sub-pixel circuit (e.g., a corner sub-pixel circuit PCc) configured to drive the corner sub-pixel PXc and a sub-pixel circuit (e.g., a main sub-pixel circuit PCm) configured to drive the main sub-pixel PXm so as to provide the same scan signal thereto. In this case, a scan line SL connected to the driving circuit SDRV1 may extend from the second corner display area CDA2 to the front display area FDA. The scan line SL may extend in the x direction.

In the second corner display area CDA2, the corner sub-pixel PXc may be disposed to overlap the driving circuit SDRV1. A corner sub-pixel circuit PCc configured to drive the corner sub-pixel PXc arranged in the second corner display area CDA2 may be arranged in the first corner display area CDA1. Accordingly, sub-pixel circuits PC1 and PC2 respectively configured to drive the corner sub-pixel PXc arranged in the first corner display area CDA1 and the corner sub-pixel PXc arranged in the second corner display area CDA2 may be arranged in the first corner display area CDA1. The corner sub-pixel PXc arranged in the second corner display area CDA2 may be driven by being connected through the connection line CWL to the sub-pixel circuits PC1 and PC2 arranged in the first corner display area CDA1. The connection line CWL may extend in the x direction, which is a direction in which the scan line SL extends.

The corner sub-pixels PXc arranged in the corner display area CDA may include a first copy sub-pixel CPX1 and a second copy sub-pixel CPX2. The first copy sub-pixel CPX1 and the second copy sub-pixel CPX2 may be sub-pixels that are driven by one sub-pixel circuit and configured to emit the same color. The size of the first copy sub-pixel CPX1 may be substantially equal to the size of the second copy sub-pixel CPX2. Because the corner sub-pixels PXc are provided as copy sub-pixels, the number of sub-pixel circuits configured to drive the corner sub-pixels PXc may be reduced. Because the corner sub-pixels PXc overlap the driving circuit SDRV1, the corner display area CDA may be expanded.

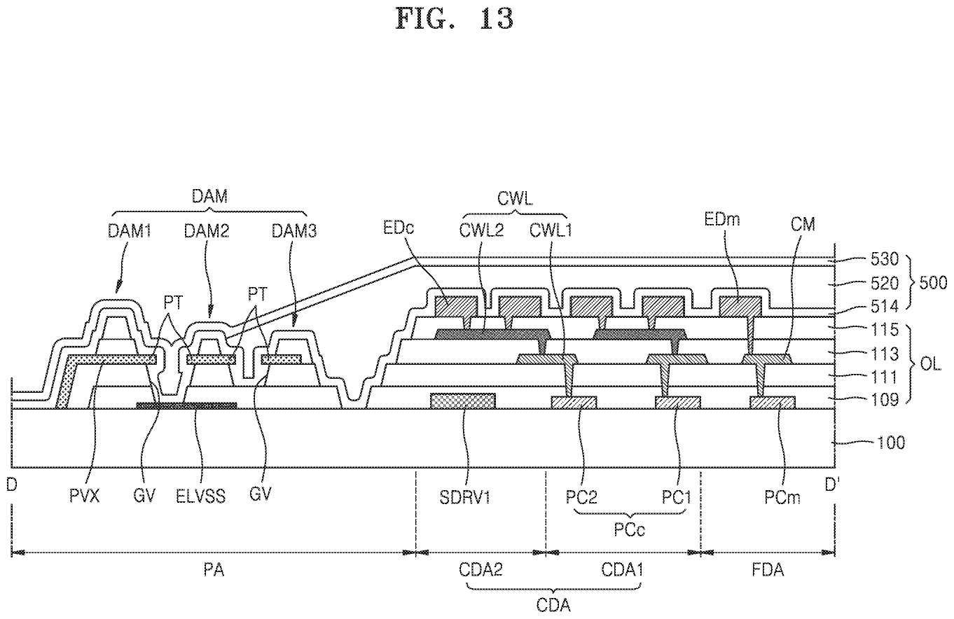

The peripheral area PA may be outside the side display area SDA and the corner display area CDA. Various wirings, a driving circuit SDRV2, a terminal 14, and a dam portion DAM (e.g., see FIG. 13) may be provided in the peripheral area PA.

The driving circuit SDRV2 may be configured to provide a scan signal for driving the main sub-pixels PXm and the side sub-pixels PXs. The driving circuit SDRV2 may be arranged on the right side of the second side display area SDA2 and/or the left side of the third side display area SDA3, and may be connected to the scan line SL extending in the x direction.

The terminal 14 may be disposed in a pad area PDA below the first side display area SDA1. The terminal 14 may be exposed without being covered by an insulating layer and may be connected to a display circuit board FPCB. A display driver 32 may be disposed on the display circuit board FPCB.

The display driver 32 may be configured to generate a control signal to be transmitted to the driving circuits SDRV1 and SDRV2. In addition, the display driver 32 may be configured to generate a data signal. The generated data signal may be transferred to the sub-pixels PXm, PXs, and PXc through a fan-out line FW and a data line DL connected to the fan-out line FW.

The dam portion DAM may be arranged in the peripheral area PA and surround the display area DA.

FIG. 13 is a schematic cross-sectional view of a portion of a display panel 10 of FIG. 12 taken along line D-D′ of FIG. 12 (see FIG. 11), according to another embodiment.

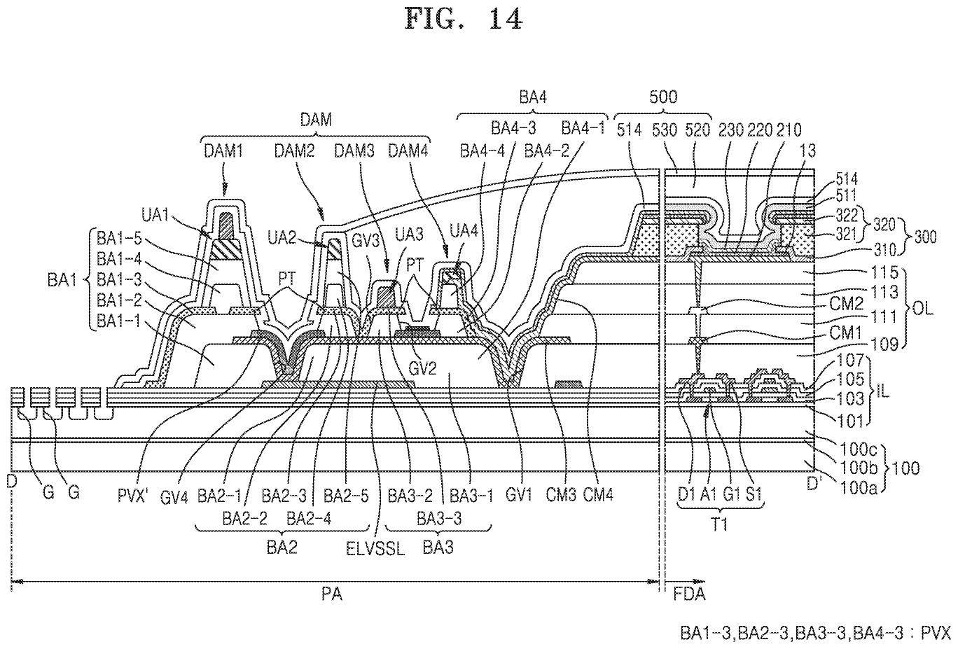

Referring to FIG. 13 and in conjunction with FIGS. 11 and 14, the display panel 10 may include a front display area FDA, a corner display area CDA, and a peripheral area PA. The corner display area CDA may include a first corner display area CDA1 and a second corner display area CDA2.

A substrate 100 may include an insulating material, such as glass, quartz, or polymer resin. The substrate 100 may be a rigid substrate or a flexible (e.g., bendable, foldable, rollable) substrate.

Sub-pixel circuits PCm and PCc including thin-film transistors, a driving circuit SDRV1 configured to provide a scan signal to the sub-pixel circuits PCm and PCc, light-emitting elements EDm and EDc respectively connected to the sub-pixel circuits PCm and PCc and implementing pixels (e.g., see pixels PXm and PXc of FIG. 12), an encapsulation layer 500 covering and protecting the light-emitting elements EDm and EDc, and a dam portion DAM may be disposed on the substrate 100. The sub-pixel circuits PCm and PCc may include a main sub-pixel circuit PCm and a corner sub-pixel circuit PCc. The corner sub-pixel circuit PCc may include a first corner sub-pixel circuit PC1 and a second corner sub-pixel circuit PC2. In some embodiments, the main sub-pixel circuit PCm, the first corner sub-pixel circuit PC1, and the second corner sub-pixel circuit PC2 may be all provided as the same sub-pixel circuit. In another embodiment, the main sub-pixel circuit PCm, the first corner sub-pixel circuit PC1, and the second corner sub-pixel circuit PC2 may be at least partially modified or may be provided as different sub-pixel circuits.

An organic layer OL may be between the main and corner sub-pixel circuits PCm and PCc and the light-emitting elements EDm and EDc. The organic layer OL may be provided by stacking a plurality of organic layers. In some embodiments, the organic layer OL may be provided by stacking a first organic layer 109, a second organic layer 111, a third organic layer 113, and a fourth organic layer 115.

The main sub-pixel circuit PCm and the main light-emitting element EDm connected thereto may be arranged in the front display area FDA of the display panel 10 (see FIG. 11). An emission area of the main light-emitting element EDm may correspond to the main sub-pixel (see the main sub-pixel PXm of FIG. 12). The main sub-pixel circuit PCm may include at least one thin-film transistor and may control light emission of the main light-emitting element EDm. The main light-emitting element EDm may be connected to the main sub-pixel circuit PCm through a connection electrode CM. The main light-emitting element EDm may at least partially overlap the main sub-pixel circuit PCm.

The first corner sub-pixel circuit PC1 and the corner light-emitting element EDc connected thereto may be arranged in the first corner display area CDA1 of the display panel 10. An emission area of the corner light-emitting element EDc may correspond to the corner sub-pixel (see the corner sub-pixel PXc of FIG. 12). The first corner sub-pixel circuit PC1 may include at least one thin-film transistor and may control light emission of at least two corner light-emitting elements EDc. In an embodiment, the two corner light-emitting elements EDc may be connected to one first corner sub-pixel circuit PC1 and configured to simultaneously emit light. In this case, the two corner light-emitting elements EDc may implement copy sub-pixels.

The second corner sub-pixel circuit PC2 connected to the corner light-emitting element EDc arranged in the second corner display area CDA2 may be arranged in the first corner display area CDA1. The second corner sub-pixel circuit PC2 may include at least one thin-film transistor and may control light emission of at least two corner light-emitting elements EDc. In an embodiment, the two corner light-emitting elements EDc may be connected to one second corner sub-pixel circuit PC2 and configured to simultaneously emit light. In this case, the two corner light-emitting elements EDc may implement copy sub-pixels.

The second corner sub-pixel circuit PC2 may be connected to the corner light-emitting element EDc arranged in the second corner display area CDA2 by the connection line CWL. The connection line CWL may include a first connection line CWL1 and a second connection line CWL2, which are arranged on different layers. The connection relationship may be variously modified. For example, the second corner sub-pixel circuit PC2 may be connected to the corner light-emitting element EDc only by the first connection line CWL1, may be connected to the corner light-emitting element EDc only by the second connection line CWL2, or may be connected to the corner light-emitting element EDc by the first connection line CWL1 and the second connection line CWL2.

A driving circuit SDRV1 may be arranged in the second corner display area CDA2 of the display panel 10. The driving circuit SDRV1 may include at least one thin-film transistor and may be configured to provide a scan signal to the sub-pixel circuits PCc and PCm respectively arranged in the corner display area CDA (e.g., the first corner display area CDA1) and the front display area FDA. An emission control driving circuit (not shown) configured to provide an emission control signal in addition to a scan signal may be further arranged in the second corner display area CDA2. The driving circuit SDRV1 and the emission control driving circuit may overlap the corner light-emitting element EDc.

The emission areas of the corner light-emitting elements EDc arranged in the first corner display area CDA1 and the second corner display area CDA2 represent corner sub-pixels. The corner sub-pixels may be arranged in the same pixel arrangement in the first corner display area CDA1 and the second corner display area CDA2.

The main light-emitting element EDm and the corner light-emitting element EDc may be covered with the encapsulation layer 500. In some embodiments, the encapsulation layer 500 may include at least one inorganic encapsulation layer and at least one organic encapsulation layer. In an embodiment, the encapsulation layer 500 may include a first inorganic encapsulation layer (not shown), a second inorganic encapsulation layer 530, an additional inorganic encapsulation layer 514, and an organic encapsulation layer 520 between the additional inorganic encapsulation layer 514 and the second inorganic encapsulation layer 530. In this case, the first inorganic encapsulation layer (not shown) may include the first-first inorganic encapsulation layer 511, the first-second inorganic encapsulation layer 512, and the first-third inorganic encapsulation layer 513 illustrated in FIG. 4A. In another embodiment, the additional inorganic encapsulation layer 514 may not be arranged and one of the first-first inorganic encapsulation layer 511, the first-second inorganic encapsulation layer 512, and the first-third inorganic encapsulation layer 513 may be arranged in the dam portion DAM and perform some roles of the additional inorganic encapsulation layer 514.

The dam portion DAM and a common power supply line ELVSSL configured to transmit a common voltage to the light-emitting element (e.g., a main light-emitting element EDm and a corner light-emitting element EDc) may be arranged in the peripheral area PA of the display panel 10. The dam portion DAM may overlap the common power supply line ELVSSL. The dam portion DAM may prevent the flow of an organic material for forming the organic encapsulation layer 520 of the encapsulation layer 500 and prevent infiltration of external moisture.

The dam portion DAM may include a plurality of dams. The dam portion DAM may include a first dam DAM1, a second dam DAM2, and a third dam DAM3. A groove GV that is concave in a depth direction may be formed between the dams DAM1, DAM2, DAM3. The dams DAM1, DAM2, DAM3 may be provided by stacking a plurality of organic layers OL, insulating layers, and conductive layers.

In the present embodiment, the second dam DAM2 and the third dam DAM3 may each include a second dam base layer (not shown) and a third dam base layer (not shown). The second dam base layer and the third dam base layer may each include a first organic layer 109, a second organic layer 111, a third organic layer 113, and a dam inorganic layer PVX between the second organic layer 111 and the third organic layer 113. The dam inorganic layer PVX may have a protruding tip PT protruding toward the center of the groove GV between the third dam DAM3 and the second dam DAM2. Because the organic layer or the second electrode included in the light-emitting element is disconnected by the protruding tip PT, a tolerance margin required when depositing the organic layer or the second electrode may be reduced, and thus, the area of the peripheral area PA may be drastically reduced. In addition, at least one of the second dam DAM2 and the third dam DAM3 may include a dam upper layer on the third organic layer 113. In this case, the dam upper layer may include at least one of a plurality of layers of the first dam upper layer UA1 described with reference to FIG. 4C or 6B.

In the present embodiment, the first dam DAM1 may include a first dam base layer (not shown) and a first dam upper layer UA1. The first dam base layer may include the first organic layer 109, the second organic layer 111, and the third organic layer 113, which are sequentially stacked. The first dam DAM1 may further include the dam inorganic layer PVX between the second organic layer 111 and the third organic layer 113. The dam inorganic layer PVX may cover the side surface of the first dam DAM1 adjacent to the edge of the substrate 100. That is, the dam inorganic layer PVX may be provided to cover one side surface of the second organic layer 111, which is the second layer of the first dam DAM1. The dam inorganic layer PVX may extend from one side surface of the second organic layer 111 to the upper surface of the substrate 100. Accordingly, the additional inorganic encapsulation layer 514 of the encapsulation layer 500 may be in contact with the dam inorganic layer PVX on the side surface of the first dam DAM1. The second inorganic encapsulation layer 530 may also be in contact with the additional inorganic encapsulation layer 514 on the side surface of the second dam DAM2.

The first dam upper layer UA1 may include at least one of a plurality of layers of the first dam upper layer UA1 described with reference to FIG. 4C or 6B.

On the other hand, the additional inorganic encapsulation layer 514 may clad the edge of the dam inorganic layer PVX on the upper surface of the substrate 100, and the second inorganic encapsulation layer 530 may clad the edge of the additional inorganic encapsulation layer 514 on the upper surface of the substrate 100. Such a structure may effectively prevent ambient air from penetrating into the display area CDA, FDA and SDA. In addition, because the additional inorganic encapsulation layer 514, the second inorganic encapsulation layer 530, and the dam inorganic layer PVX are in contact with each other on the side surface of the first dam DAM1, the area of the peripheral area PA may be drastically reduced. As the area of the peripheral area PA is reduced, the area of the second corner display area CDA2 may be increased. This may mean that the area of the display area CDA, FDA and SDA of the display apparatus 1 (e.g., see FIG. 7) is increased.

FIG. 14 is a cross-sectional view schematically illustrating a portion of a display panel, according to another embodiment. FIG. 14 is a cross-sectional view of the display panel of FIG. 12 taken along line D-D′ of FIG. 12.

Referring to FIG. 14, a dam portion DAM including a plurality of dams may be arranged in a peripheral area PA. The dam portion DAM may be a member that, when an organic encapsulation layer 520 of an encapsulation layer 500 is formed, blocks the flow of an organic material for forming the organic encapsulation layer 520.

The dam portion DAM may include a first dam DAM1, a second dam DAM2, a third dam DAM3, and a fourth dam DAM4. The first dam DAM1, the second dam DAM2, the third dam DAM3, and the fourth dam DAM4 may be provided by stacking a plurality of organic layers, a dam inorganic layer PVX, a conductive layer, and an insulating layer.

The dam inorganic layer PVX may include an inorganic insulating material. For example, the dam inorganic layer PVX may include a single layer or layers including an inorganic insulating material, such as silicon oxide (SiOx) or silicon nitride (SiNx). When the dam inorganic layer PVX includes an inorganic insulating material, the dam inorganic layer PVX may be formed by a separate mask process.

In another embodiment, the dam inorganic layer PVX may include a metal material. For example, the dam inorganic layer PVX may include a metal material, such as molybdenum (Mo), aluminum (Al), copper (Cu), or titanium (Ti), and may include a single layer or layers including the metal material described above. When the dam inorganic layer PVX includes a metal material, the dam inorganic layer PVX may be formed of the same material as that of the second connection electrode CM2 and formed simultaneously with the second connection electrode CM2.

The first dam DAM1 may be the outermost dam among the dams of the dam portion DAM. The first dam DAM1 may include a first dam base layer BA1 and a first dam upper layer UA1. The first dam base layer BA1 may include a first-first dam base layer BA1-1 including the same material as that of the first organic layer 109, a first-second dam base layer BA1-2 including the same material as that of the second organic layer 111, a first-third dam base layer BA1-3 provided as the dam inorganic layer PVX, a first-fourth dam base layer BA1-4 including the same material as that of the third organic layer 113, and a first-fifth dam base layer BA1-5 including the same material as that of the fourth organic layer 115. The first dam upper layer UA1 may be disposed on the first dam base layer BA1 and may include at least one of a conductive layer and an insulating layer. For example, the first dam upper layer UA1 may include three dam upper layers that are sequentially stacked. The number of layers constituting the first dam upper layer UA1 is not limited to three, and the layers constituting the first dam upper layer UA1 may be variously arranged. In this case, the first dam upper layer UA1 may include at least one of a plurality of layers of the first dam upper layer UA1 described with reference to FIG. 4C or 6B.

The height of the first dam DAM1 may be greater than the height of the second dam DAM2. The dam inorganic layer PVX may be disposed to cover the upper surface and the side surface of the second layer including the same material as that of the second organic layer 111.

The second dam DAM2 may be outside the third dam DAM3 and may include a second dam base layer BA2 and a second dam upper layer UA2. The second dam base layer BA2 may include a second-first dam base layer BA2-1 including the same material as that of the first organic layer 109, a second-second dam base layer BA2-2 including the same material as that of the second organic layer 111, a second-third dam base layer BA2-3 provided as the dam inorganic layer PVX, a second-fourth dam base layer BA2-4 including the same material as that of the third organic layer 113, and a second-fifth dam base layer BA2-5 including the same material as that of the fourth organic layer 115. The second dam upper layer UA1 may include at least one of a plurality of layers of the first dam upper layer UA1 described with reference to FIG. 4C or 6B. The height of the second dam DAM2 may be greater than the height of the fourth dam DAM4 and the height of the third dam DAM3.

A fourth groove GV4 may be between the second-first dam base layer BA2-1 of the second dam DAM2 and the first-first dam base layer BA1-1 of the first dam DAM1. The second-first dam base layer BA2-1 of the second dam DAM2 and the first-first dam base layer BA1-1 of the first dam DAM1 may be spaced apart from each other. A common power supply line ELVSSL may be disposed below the second dam DAM2 and the first dam DAM1. The common power supply line ELVSSL may be configured to transmit a common voltage to the light-emitting elements and may be electrically connected to the second electrode 230.

In some embodiments, the common power supply line ELVSSL may be connected to the bank layer 320 through the third connection electrode CM3 and the fourth connection electrode CM4. The fourth groove GV4 may function as a contact hole connecting the common power supply line ELVSSL to the third connection electrode CM3. The common power supply line ELVSSL may be arranged on the same layer as a first source electrode S1 and/or a first drain electrode D1 of a first thin-film transistor T1. The first common power supply line ELVSSL may be disposed on a second interlayer insulating layer 107. The first common power supply line ELVSSL may be exposed by the fourth groove GV4. The third connection electrode CM3 may be arranged on the same layer as the first connection electrode CM1 and may include the same material as that of the first connection electrode CM1. The third connection electrode CM3 may be arranged inside the first to fourth dams DAM1 to DAM4 and may be disposed on the first organic layer 109.

The third connection electrode CM3 may be in direct contact with the common power supply line ELVSSL through the fourth groove GV4. The third connection electrode CM3 may extend from the fourth groove GV4 to the first groove GV1. The third connection electrode CM3 may be in direct contact with the fourth connection electrode CM4 on the side surface of the fourth dam DAM4 or in the first groove GV1. The fourth connection electrode CM4 may include the same material as that of the first electrode 210. The fourth connection electrode CM4 may be in direct contact with the bank layer 320 in or around the first groove GV1.

The third dam DAM3 may be outside the fourth dam DAM4 and may include a third dam base layer BA3 and a third dam upper layer UA3. The third dam base layer BA3 may include a third-first dam base layer BA3-1 including the same material as that of the first organic layer 109, a third-second dam base layer BA3-2 including the same material as that of the second organic layer 111, and a third-third dam base layer BA3-3 provided as the dam inorganic layer PVX. The third dam upper layer UA3 may be disposed on the third-third dam base layer BA3-3 and may include at least one of a plurality of layers of the first dam upper layer UA1 described with reference to FIG. 4C or 6B. The height of the third dam DAM3 may be less than the height of the fourth dam DAM4.

The second-first dam base layer BA2-1 and the third-first dam base layer BA3-1 may be connected to each other, and the second-third dam base layer BA2-3 and the third-third dam base layer BA3-3 may be connected to each other. In this case, a third groove GV3 may be between the second-second dam base layer BA2-2 and the third-second dam base layer BA3-2. The second-second dam base layer BA2-2 and the third-second dam base layer BA3-2 may be spaced apart from each other.

The fourth dam DAM4 may be disposed closest to the display area (e.g., the front display area FDA) and may include a fourth dam base layer BA4 and a fourth dam upper layer UA4. The fourth dam base layer BA4 may include a fourth-first dam base layer BA4-1 including the same material as that of the first organic layer 109, a fourth-second dam base layer BA4-2 including the same material as that of the second organic layer 111, a fourth-third dam base layer BA4-3 provided as the dam inorganic layer PVX, and a fourth-fourth dam base layer BA4-4 including the same material as that of the third organic layer 113. The fourth dam upper layer UA4 may be disposed on the fourth dam base layer BA4 and may include at least one of a plurality of layers of the first dam upper layer UA1 described with reference to FIG. 4C or 6B.

The fourth dam DAM4 may be spaced apart from the organic layer OL extending from the display area. The first groove GV1 may be formed between the fourth dam DAM4 and the organic layer OL. That is, the first groove GV1 exposing the upper surface of the inorganic insulating layer IL may be formed between the dam portion DAM and the organic layer OL. Because the first groove GV1 is formed, ambient air that may penetrate into the display area may be blocked.

The third-first dam base layer BA3-1 and the fourth-first dam base layer BA4-1 may be integrally formed as a single body. The second groove GV2 may be between the third-second dam base layer BA3-2 and the fourth-second dam base layer BA4-2. The second layers of the third-second dam base layer BA3-2 and the fourth-second dam base layer BA4-2 may be spaced apart from each other. The dam inorganic layer PVX may include a protruding tip PT protruding toward the second groove GV2 between the fourth dam DAM4 and the third dam DAM3.

An organic encapsulation layer 520 may be arranged inside the second dam DAM2. However, the disclosure is not limited thereto. The organic encapsulation layer 520 may be variously modified. For example, the organic encapsulation layer 520 may be arranged inside the first dam DAM1.

An additional inorganic encapsulation layer 514 and a second inorganic encapsulation layer 530 may be in contact with each other from a partial area of the dam portion DAM and may pass through the dam portion DAM and extend to the edge of the substrate 100. For example, the additional inorganic encapsulation layer 514 and the second inorganic encapsulation layer 530 may be in contact with each other from the upper surface of the second dam DAM2 and extend to the edge of the substrate 100.

In the above case, a light-emitting element including a first electrode 210, an intermediate layer 220, and a second electrode 230 may be arranged in a front display area FDA, as described with reference to FIGS. 7 to 12. A first-first inorganic encapsulation layer 511 may be disposed on the light-emitting element. In addition, the light-emitting element may include a plurality of light-emitting elements configured to emit pieces of light of different colors, as illustrated in FIG. 4A as well as FIG. 13. A first-second inorganic encapsulation layer (not shown) and a first-third inorganic encapsulation layer (not shown) may be spaced apart from each other on the light emitting element.

At least a portion of the dam inorganic layer PVX included in the first dam DAM1, which is the outermost dam, may be arranged on the side surface closest to the edge of the substrate 100 among the side surfaces of the first dam DAM1. The additional inorganic encapsulation layer 514 may be in direct contact with the dam inorganic layer PVX on the side surface of the first dam DAM1. The second inorganic encapsulation layer 530 may be in direct contact with the additional inorganic encapsulation layer 514 on the side surface of the first dam DAM1.

When the dam inorganic layer PVX is not arranged on the side surface of the first dam DAM1, which is the outermost dam, in order that the encapsulation layer 500 is able to block ambient air, the additional inorganic encapsulation layer 514 and the second inorganic encapsulation layer 530 are required to contact the upper surface of the inorganic insulating layer IL extending from the display area by a certain area or more.

However, in the present embodiment, because the dam inorganic layer PVX is arranged on the side surface of the first dam DAM1, the contact area with the inorganic layers on the side surface of the first dam DAM1 may be secured. Accordingly, even when the contact area with the inorganic insulating layer IL on the upper surface of the substrate 100 is reduced, ambient air may be sufficiently blocked. Consequently, the area of the peripheral area PA may be reduced. As the area of the peripheral area PA is reduced, the area of the display area of the display apparatus 1 (e.g., see FIG. 7) may increase.

On the other hand, the additional inorganic encapsulation layer 514 may clad the edge of the dam inorganic layer PVX on the upper surface of the substrate 100, and the second inorganic encapsulation layer 530 may clad the edge of the additional inorganic encapsulation layer 514 on the upper surface of the substrate 100. Such a structure may effectively prevent ambient air from penetrating into the display area.

Although it is illustrated that the additional inorganic encapsulation layer 514 and the second inorganic encapsulation layer 530 are spaced apart from the edge of the substrate 100, the disclosure is not limited thereto. In some embodiments, the additional inorganic encapsulation layer 514 and the second inorganic encapsulation layer 530 may extend to the edge of the substrate 100.

The substrate 100 may include multiple layers. For example, the substrate 100 may include a first base layer 100a, a first barrier layer 100b, a second base layer 100c, and a second barrier layer (not shown), which are sequentially stacked in this stated order.

The first base layer 100a and the second base layer 100c may each include polymer resin. For example, the first base layer 100a and the second base layer 100c may each include polymer resin, such as polyethersulfone (PES), polyarylate (PA), polyetherimide (PEI), polyethylene naphthalate (PEN), polyethylene terephthalate (PET), polyphenylene sulfide (PPS), polyimide (PI), polycarbonate (PC), cellulose triacetate (TAC), or cellulose acetate propionate (CAP). The polymer resin may be transparent.

The first barrier layer 100b and the second barrier layer are barrier layers configured to prevent infiltration of foreign matter, and may include a single layer or layers including an inorganic material, such as silicon nitride (SiNx) and/or silicon oxide (SiOx).

A plurality of grooves G formed by partially removing the inorganic insulating layer IL and the substrate 100 may be between the edge of the substrate 100 and the dam portion DAM. For example, the grooves G may be formed by connecting holes passing through the inorganic insulating layer IL to recesses formed in the second base layer 100c of the substrate 100. The inorganic insulating layer IL may have a protruding tip protruding into the groove G. The grooves G may prevent propagation of cracks that may occur when cutting the edge of the substrate 100.

In the present embodiment, an inorganic protective layer PVX′ may be disposed on the third connection electrode CM3. The inorganic protective layer PVX′ may be formed to cover a portion of the third connection electrode CM3 in order to prevent the third connection electrode CM3 from being damaged by an etchant used to etch the first electrode 210. The inorganic protective layer PVX′ may include an inorganic material, such as silicon nitride (SiNx) and/or silicon oxide (SiOx).

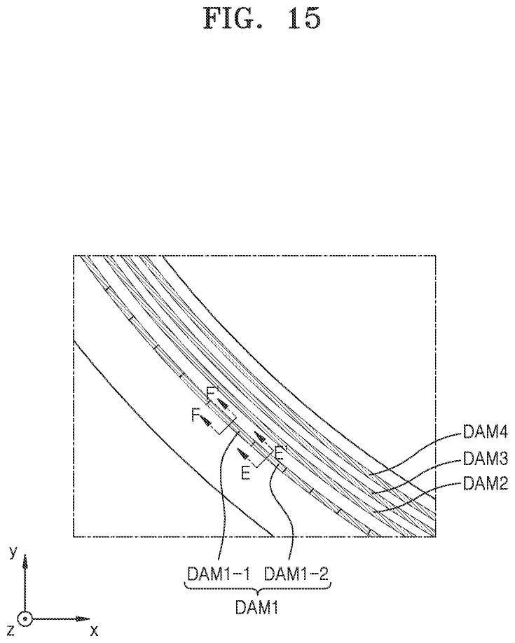

FIG. 15 is a plan view schematically illustrating a portion of a display panel, according to another embodiment.

Referring to FIG. 15, at least one of a plurality of dams of the dam portion DAM may include portions having different heights. Hereinafter, for convenience of explanation, a case where the first dam DAM1 includes portions having different heights is described in detail.

A first dam DAM1 may include a first portion DAM1-1 and a second portion DAM1-2, which have different heights. In this case, the height of one of the first portion DAM1-1 and the second portion DAM1-2 may be less than the height of the other of the first portion DAM1-1 and the second portion DAM1-2. In this case, the first portion DAM1-1 and the second portion DAM1-2 may be connected to each other.

In the first dam DAM1, the first portion DAM1-1 and the second portion DAM1-2, which have different heights, may be arranged adjacent to at least a portion of the periphery of the display area. In particular, the first portion DAM1-1 and the second portion DAM1-2 may be arranged in the corner display area CDA where the first dam DAM1 is round, as illustrated in FIG. 12. When the display panel 10 (e.g., see FIG. 11) is bent or round in the corner display area CDA, it is possible to prevent the deformation of the corner area display area CDA from being hindered by the first dam DAM1.

In the above case, the height of the first dam DAM1 may be greater than the height of the second dam DAM2, the height of the third dam DAM3, and the height of the fourth dam DAM4. That is, the height of the lowest portion among the heights of the first dam DAM1 may be greater than the height of the second dam DAM2, the height of the third dam DAM3, and the height of the fourth dam DAM4.

On the other hand, although not illustrated, the first portion DAM1-1 and the second portion DAM1-2 may be arranged in at least one of the second dam DAM2, the third dam DAM3, and the fourth dam DAM4, as well as the first dam DAM1.

In the above case, the height of the lowest portion of the second dam DAM2 may be greater than the height of the lowest portion of the third dam DAM3 and/or the height of the lowest portion of the fourth dam DAM4.

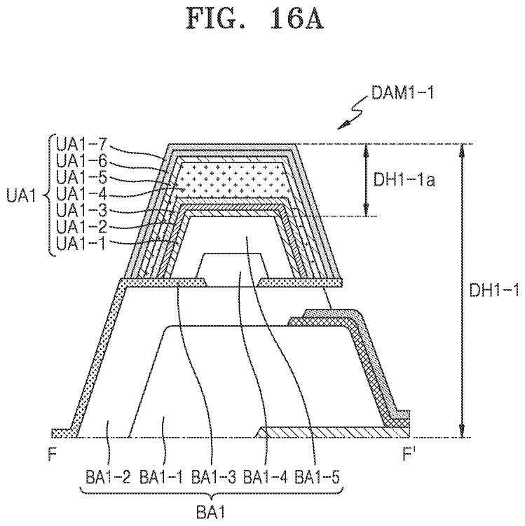

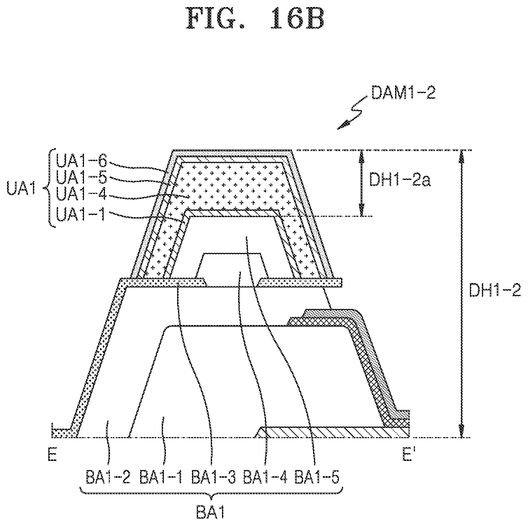

FIGS. 16A and 16B are respectively cross-sectional views illustrating a portion of a dam of FIG. 15 taken along lines F-F′ and E-E′ of FIG. 15.

Referring to FIGS. 16A and 16B, in order to make a height DH1-1 of the first portion DAM1-1 and a height DH1-2 of the second portion DAM1-2 different from each other, a height DH1-1a of the first dam upper layer UA1 of the first portion DAM1-1 and a height DH1-2a of the first dam upper layer UA1 of the second portion DAM1-2 are made different from each other. To this end, the height of at least one of the layers included in the first dam upper layer UA1 of each portion may be adjusted, or the number of layers included in the first dam upper layer UA1 may be adjusted. For convenience of explanation, a case where the height of the first dam upper layer UA1 is adjusted by adjusting the number of layers included in the first dam upper layer UA1 is described in detail.

Specifically, the first dam upper layer UA1 arranged in the first portion DAM1-1 may include a first-first dam upper layer UA1-1, a first-second dam upper layer UA1-2, a first-third dam upper layer UA1-3, a first-fourth dam upper layer UA1-4, a first-fifth dam upper layer UA1-5, a first-sixth dam upper layer UA1-6, and a first-seventh dam upper layer UA1-7. The first-first dam upper layer UA1-1, the first-second dam upper layer UA1-2, the first-third dam upper layer UA1-3, the first-fourth dam upper layer UA1-4, the first-fifth dam upper layer UA1-5, the first-sixth dam upper layer UA1-6, and the first-seventh dam upper layer UA1-7 may each include at least one of the layers of the first dam upper layer UA1 described with reference to FIG. 4C or 6B.

The first dam upper layer UA1 arranged in the second portion DAM1-2 may include a first-first dam upper layer UA1-1, a first-fourth dam upper layer UA1-4, a first-fifth dam upper layer UA1-5, and a first-sixth dam upper layer UA1-6. The first-first dam upper layer UA1-1, the first-fourth dam upper layer UA1-4, the first-fifth dam upper layer UA1-5, and the first-sixth dam upper layer UA1-6 may include at least one of the layers of the first dam upper layer UA1 described with reference to FIG. 4C or 6B.

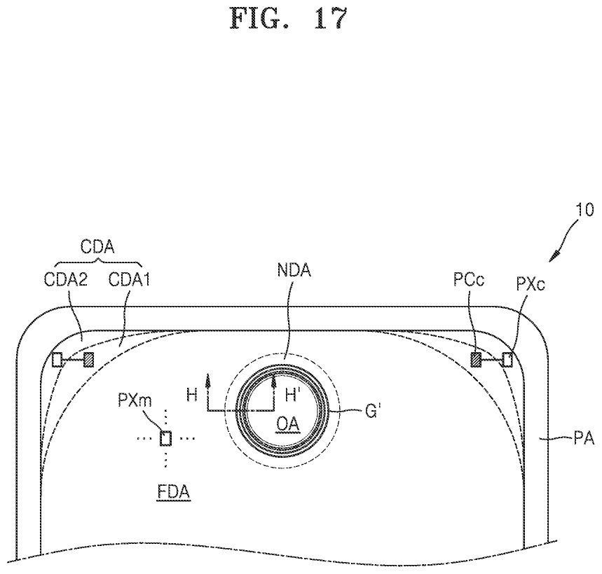

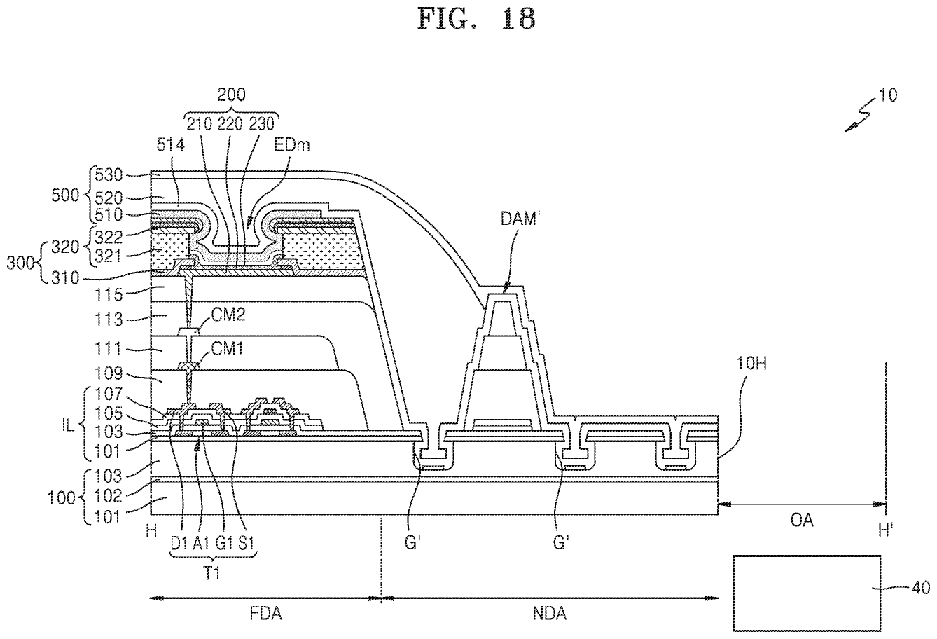

FIG. 17 is a plan view schematically illustrating a state in which a portion of the display panel 10 is unfolded, according to another embodiment. FIG. 18 is a schematic cross-sectional view of the display panel 10 of FIG. 17 taken along line H-H′ of FIG. 17.

Referring to FIGS. 17 and 18, the display panel 10 may include an opening area OA arranged inside the front display area FDA and a non-display area NDA surrounding the opening area OA. Redundant descriptions of elements having the same reference numerals as those described above.

The planar shape of the opening area OA may be various shapes, such as a circular shape, an elliptical shape, a polygonal shape (e.g., a rectangular shape a star shape, or a diamond shape). The position of the opening area OA may also be variously modified. For example, as illustrated in FIG. 17, the opening area OA may be arranged in the upper center of the front display area FDA, or unlike as illustrated, the opening area OA may be arranged in the right center or left center of the front display area FDA.

A component 40 that is an electronic element may be disposed below the display panel 10 corresponding to the opening area OA. The component 40 is a camera that uses infrared light or visible light, and may include an imaging device. Alternatively, the component 40 may be a solar cell, a flash, an illumination sensor, a proximity sensor, or an iris sensor. Alternatively, the component 40 may have a function of receiving sound.

Referring back to FIG. 17, the non-display area NDA may surround the opening area OA. The non-display area NDA is an area in which display elements such as light-emitting elements are not arranged. Signal lines configured to provide signals to the pixels PXm around the opening area OA may pass through the non-display area NDA, or an additional groove G′ may be arranged in the non-display area NDA.

Although FIG. 17 illustrates that three additional grooves G′ are located in the non-display area NDA, the disclosure is not limited thereto. In another embodiment, one, two, or four or more grooves may be arranged in the non-display area NDA.

The additional grooves G′ may have a ring shape completely surrounding the opening area OA in a non-display area NDA. The diameter of each of the additional grooves G′ may be greater than the diameter of the opening area OA. The additional grooves G′ surrounding the opening area OA in a plan view may be spaced apart from each other at certain intervals.

Referring to FIG. 18, the display panel 10 may include a first opening 10H corresponding to the opening area OA. The main light-emitting element EDm may be arranged in the front display area FDA, and the second electrode 230 of the main light-emitting element EDm may extend into the non-display area NDA.

A plurality of additional grooves G′ may be arranged in the non-display area NDA. The additional groove G′ may be formed by spatially connecting recesses, from which the second base layer 103 of the substrate 100 is partially removed, to holes passing through the inorganic insulating layer IL.

The inorganic insulating layer IL may have a protruding tip protruding toward the additional groove G′. The second electrode 230 and an organic layer (not shown) that may be included in the main light-emitting element EDm may be disconnected from each other with respect to the additional groove G′ by the protruding tip of the inorganic insulating layer IL.

The additional inorganic encapsulation layer 514 of the encapsulation layer 500 has relatively better step coverage than the second electrode 230. Accordingly, the additional inorganic encapsulation layer 514 may be continuously formed without being disconnected from the additional groove G′.

An additional dam DAM′ may be arranged in the non-display area NDA, and the additional dam DAM′ may block the flow of an organic material for forming the organic encapsulation layer 520. The additional inorganic encapsulation layer 514 and the second inorganic encapsulation layer 530 may be in contact with each other between the additional dam DAM′ and the opening area OA. In this case, the additional dam DAM′ may have a shape that is identical to or similar to one of the first to fourth dams DAM1 to DAM4 described above with reference to FIG. 14.

The display apparatuses according to embodiments may precisely control the position of the organic encapsulation layer by blocking the flow of an organic material for forming the organic encapsulation layer. The display apparatuses according to embodiments may improve moisture permeation prevention performance. These effects are only examples and the scope of the disclosure is not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus, wherein the display apparatus comprises:
a substrate comprising a display area and a peripheral area;
a dam portion arranged in the peripheral area of the substrate and comprising a plurality of dams; and
an encapsulation layer disposed on the substrate and the dam portion,
wherein at least one of the plurality of dams comprises:
at least one first layer comprising an organic layer; and
a second layer disposed on the first layer and comprising at least one of a conductive layer and an inorganic layer.

2. The display apparatus of claim 1, wherein the at least one of the conductive layer and the inorganic layer is provided in plurality and the plurality of conductive layers, the plurality of inorganic layers, or the conductive layer and the inorganic layer are stacked.

3. The display apparatus of claim 1, wherein
the inorganic layer comprises a plurality of inorganic layers, and
the dam portion further comprises a planarization layer between one of the plurality of inorganic layers and another of the plurality of inorganic layers.

4. The display apparatus of claim 1, wherein a height of one of the plurality of dams is different from a height of another of the plurality of dams.

5. The display apparatus of claim 1, wherein a height of an outermost dam of the plurality of dams is greater than a height of an innermost dam of the plurality of dams.

6. The display apparatus of claim 1, wherein a number of second layers of one of the plurality of dams is different from a number of second layers of another of the plurality of dams.

7. The display apparatus of claim 1, further comprising:
a first electrode disposed on the substrate;
an insulating layer arranged at an edge of the first electrode and having an opening overlapping a portion of the first electrode;
a protective layer disposed on the insulating layer, surrounding a periphery of the first electrode, and having an opening overlapping a portion of the first electrode;
a bank layer disposed on the protective layer and having an opening overlapping a portion of the first electrode;
a second electrode spaced apart from the first electrode; and
a sub-pixel encapsulation layer disposed on the first electrode.

8. The display apparatus of claim 7, wherein
the bank layer comprises:
a first metal layer; and
a second metal layer disposed on the first metal layer.

9. The display apparatus of claim 7, wherein the inorganic layer comprises at least one of the protective layer, the insulating layer, and the sub-pixel encapsulation layer.

10. The display apparatus of claim 7, wherein the conductive layer comprises at least one of the first electrode, the bank layer, and the second electrode.

11. The display apparatus of claim 1, wherein the second layer surrounds the first layer.

12. The display apparatus of claim 1, wherein the display apparatus further comprises a groove spaced apart from the dam portion.

13. A display apparatus, wherein the display apparatus comprises:
a substrate comprising a display area and a peripheral area;
a dam arranged in the peripheral area of the substrate in a single line shape surrounding at least a portion of a periphery of the display area; and
an encapsulation layer disposed on the substrate and the dam,
wherein the dam comprises:
at least one first layer comprising an organic layer; and
a second layer disposed on the first layer and comprising at least one of a conductive layer and an inorganic layer,
wherein a height of a first portion of the dam is different from a height of a second portion of the dam.

14. The display apparatus of claim 13, wherein the at least one of the conductive layer and the inorganic layer is provided as a plurality of conductive layers or a plurality of inorganic layers, and the plurality of conductive layers, the plurality of inorganic layers, or the conductive layer and the inorganic layer are stacked.

15. The display apparatus of claim 13, wherein
the inorganic layer comprises a plurality of inorganic layers, and
the dam further comprises a planarization layer between one of the plurality of inorganic layers and another of the plurality of inorganic layers.

16. The display apparatus of claim 13, wherein
the dam comprises a plurality of dams, and
a height of a highest point of one of the plurality of dams is different from a height of a highest point of another of the plurality of dams.

17. The display apparatus of claim 13, wherein
the dam comprises a plurality of dams, and
a height of an outermost dam of the plurality of dams is greater than a height of an innermost dam of the plurality of dams.

18. The display apparatus of claim 13, wherein
the dam comprises a plurality of dams, and
a number of second layers of one of the plurality of dams is different from a number of second layers of another of the plurality of dams.

19. The display apparatus of claim 13, wherein a number of second layers in the first portion of the dam is different from a number of second layers in the second portion of the dam.

20. The display apparatus of claim 13, wherein the second layer surrounds the first layer.

21. The display apparatus of claim 13, further comprising a groove spaced apart from the dam.

22. The display apparatus of claim 13, wherein the first portion of the dam and the second portion of the dam, which have different heights, are arranged in a curved portion of the single line shape.

23. The display apparatus of claim 13, wherein further comprising
a first electrode disposed on the substrate;
an insulating layer arranged at an edge of the first electrode and having an opening overlapping a portion of the first electrode;
a protective layer disposed on the insulating layer, surrounding a periphery of the first electrode, and having an opening overlapping a portion of the first electrode;
a bank layer disposed on the protective layer and having an overlapping opening a portion of the first electrode;
a second electrode spaced apart from the first electrode; and
a sub-pixel encapsulation layer disposed on the first electrode.

24. The display apparatus of claim 23, wherein the conductive layer comprises at least one of the first electrode, the bank layer, and the second electrode.

25. The display apparatus of claim 23, wherein the inorganic layer comprises at least one of the protective layer, the insulating layer, and the sub-pixel encapsulation layer.
